(19) United States
(12) Patent Application Publication
(10) Pub. No.: US 2026/0171375 A1
(43) Pub. Date: Jun. 18, 2026

(54) SUBSTRATE PROCESSING APPARATUS AND METHOD OF PROCESSING SUBSTRATE

(71) Applicant: SCREEN Holdings Co., Ltd., Kyoto (JP)

(72) Inventors: Atsushi KUROEDA, Kyoto-shi (JP); Hikaru FUJIWARA, Kyoto-shi (JP)

(21) Appl. No.: 19/417,291

(22) Filed: Dec. 11, 2025

(30) Foreign Application Priority Data
Dec. 18, 2024 (JP) 2024-221498

(51) Int. Cl. H01J 37/32

(52) U.S. Cl. CPC H01J 37/32834; H01J 37/32889; H01J 2237/334

(57) ABSTRACT

A substrate processing apparatus includes an upstream chamber, an upstream pressure regulator, a dry processing chamber, a transporter, and a controller. The dry processing chamber is connected to the upstream chamber through a first gate. The transporter transports a substrate between the upstream chamber and the dry processing chamber through the opened first gate. The controller controls the upstream pressure regulator such that a pressure in the upstream chamber is set to a first pressure value higher than a pressure in the dry processing chamber, opens the first gate and controls the transporter such that the substrate is transported while the pressure in the upstream chamber is set to the first pressure value, and controls the upstream pressure regulator such that the pressure in the upstream chamber is reduced to a second pressure value lower than the first pressure value while the first gate is closed.

### BACKGROUND

### Technical Field

The present disclosure relates to a substrate processing apparatus and a method of processing a substrate.

### Description of the Background Art

Substrate processing apparatuses each processing a substrate have conventionally been proposed (for example, Japanese Patent Application Laid-Open No. 2017-157705, Japanese Patent Application Laid-Open No. 2020-53476, and Japanese Patent Application Laid-Open No. 2007-186757). In each of Japanese Patent Application Laid-Open No. 2017-157705, Japanese Patent Application Laid-Open No. 2020-53476, and Japanese Patent Application Laid-Open No. 2007-186757, a substrate processing apparatus includes a plurality of processing chambers that perform dry processes on substrates in a vacuum condition, and a transporter that transports the substrates to the processing chambers. A transport chamber including the transporter is connected to each of the processing chambers through a gate valve. The substrate processing apparatus includes a pressure regulator that regulates a pressure in the transport chamber. In the substrate processing apparatus, each of the gate valves is opened while a pressure in the transport chamber is higher than those of the processing chambers, and the transporter loads and unloads the substrate into and out of each of the processing chambers through the gate valve.

### SUMMARY

According to one aspect, a substrate processing apparatus includes: an upstream chamber; an upstream pressure regulator that supplies gas to the upstream chamber and suctions the gas from the upstream chamber to regulate a pressure in the upstream chamber; a dry processing chamber that is connected to the upstream chamber through a first gate and that performs a dry process on a substrate while the first gate is closed; a transporter that transports the substrate between the upstream chamber and the dry processing chamber through the first gate that is opened; and a controller that controls the upstream pressure regulator such that a pressure in the upstream chamber is set to a first pressure value higher than a pressure in the dry processing chamber, opens the first gate and controls the transporter such that the substrate is transported while the pressure in the upstream chamber is set to the first pressure value, and controls the upstream pressure regulator such that the pressure in the upstream chamber is reduced to a second pressure value lower than the first pressure value while the first gate is closed.

According to one aspect, a method of processing a substrate includes: opening a first gate between an upstream chamber and a dry processing chamber and transporting a substrate between the upstream chamber and the dry processing chamber using a transporter, while a pressure in the upstream chamber is set to a first pressure value higher than a pressure in the dry processing chamber; and reducing the pressure in the upstream chamber to a second pressure value lower than the first pressure value while the first gate is closed.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically illustrating an example structure of a substrate processing apparatus;

FIG. 2 schematically illustrating one example internal configuration of a controller;

FIG. 3 is a vertical cross-sectional view schematically illustrating one example specific structure of dry processing modules;

FIG. 4 illustrates graphs indicating example time variations in a pressure in a local transport chamber and a pressure in a dry processing chamber;

FIG. 5 illustrates graphs indicating example time variations in the pressure in the load lock chamber and the pressure in the local transport chamber;

FIG. 6 is a flowchart illustrating example operations of the dry processing module;

FIG. 7 is a flowchart illustrating example operations of the dry processing module;

FIG. 8 is a diagram schematically illustrating example state changes during operations of the dry processing module according to Embodiment 1;

FIG. 9 is a diagram schematically illustrating example state changes during operations of the dry processing module according to Embodiment 1;

FIG. 10 is a diagram illustrating example time variations in pressures in the load lock chamber, the local transport chamber, and the dry processing chamber;

FIG. 11 is a diagram schematically illustrating an example structure of a transport system of a dry processing module according to Embodiment 2;

FIG. 12 is a diagram schematically illustrating example state changes during operations of the dry processing module according to Embodiment 2;

FIG. 13 is a diagram schematically illustrating example state changes during operations of the dry processing module according to Embodiment 2;

FIG. 14 is a diagram schematically illustrating example state changes during operations of the dry processing module according to Embodiment 2; and

FIG. 15 is a diagram schematically illustrating example state changes during operations of the dry processing module according to Embodiment 2.

### DESCRIPTION OF THE PREFERRED EMBODIMENTS

In Japanese Patent Application Laid-Open No. 2017-157705, Japanese Patent Application Laid-Open No. 2020-53476, and Japanese Patent Application Laid-Open No. 2007-186757, when gas and impurities in a processing chamber slightly flow into a transport chamber through a gate valve, there is a danger that the impurities may flow into another processing chamber connected to the transport chamber. Thus, there is a danger that a substrate may be contaminated by the other processing chamber.

Thus, the present disclosure has an object of providing a technology that can reduce the possibility of contaminating a substrate.

Embodiments will be described in detail below with reference to drawings. It should be noted that dimensions and the number of components are shown in exaggeration or in simplified form as appropriate for the sake of easier understanding. The same reference signs are assigned to parts having similar structures and functions, and overlapping description will be omitted in the following description.

In the following description, the same reference signs are assigned to the same constituent elements, and their names and functions are the same. Therefore, detailed description of such constituent elements may be omitted to avoid redundant description.

Even when the ordinal numbers such as “first” and “second” are used in the following description, these terms are used for convenience to facilitate the understanding of the details of Embodiments. The order indicated by these ordinal numbers does not restrict the details of Embodiments.

Unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, and “homogeneous”) include those indicating quantitatively exact equality and those in the presence of a difference within tolerance or to the extent that similar functions can be obtained. Unless otherwise noted, the expressions indicating shapes (e.g., “rectangular” or “cylindrical”) include those indicating geometrically exact shapes and those indicating, for example, roughness or a chamfer to the extent that similar advantages can be obtained. An expression “comprising”, “including”, “containing”, or “having” one constituent element is not an exclusive expression for excluding the presence of the other constituent elements. An expression “at least one of A, B, and C” involves “only A”, “only B”, “only C”, “any two of A, B, and C”, and “all of A, B, and C”.

### Embodiment 1

### [Overall Structure of Substrate Processing Apparatus]

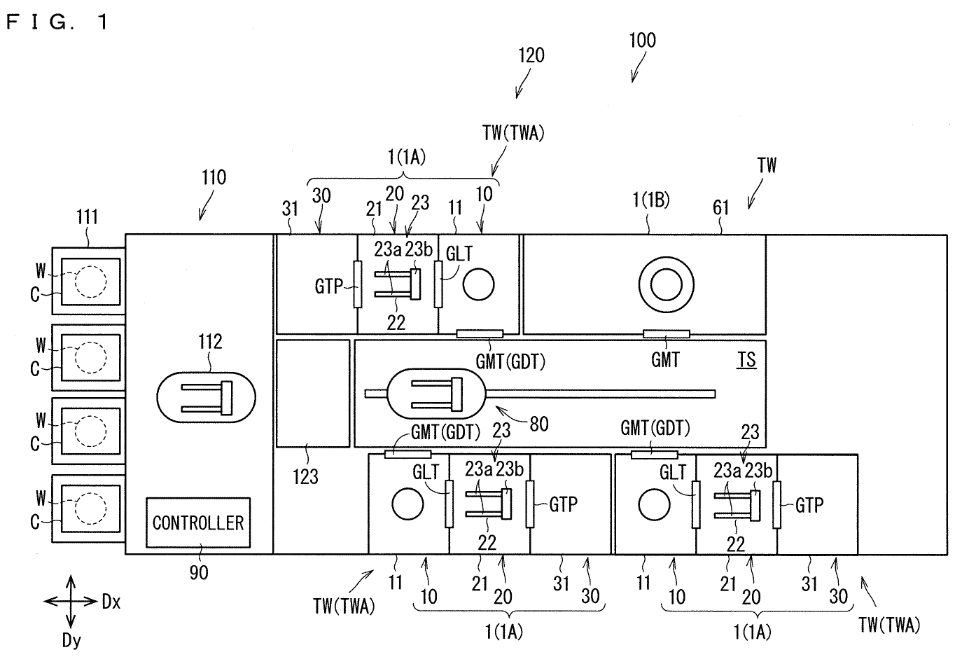

FIG. 1 is a plan view schematically illustrating an example structure of a substrate processing apparatus 100. The substrate processing apparatus 100 is a single-wafer processing apparatus that processes substrates W one by one.

Examples of the substrates W include a semiconductor wafer, a liquid crystal display substrate, an organic electroluminescence (EL) substrate, a flat panel display (FPD) substrate, an optical display substrate, a magnetic disk substrate, an optical disk substrate, a magneto-optical disk substrate, a photomask substrate, and a solar cell substrate. The substrates W have a thin plate shape. The substrates W are semiconductor wafers. For example, the substrates W are silicon substrates. The substrates W are, for example, disk-shaped. Each of the substrates W has a diameter of, for example, approximately 300 mm, and has a thickness of, for example, approximately more than or equal to 0.5 mm and less than or equal to 3 mm.

In the example of FIG. 1, the substrate processing apparatus 100 includes an indexer block 110, a processing block 120, and a controller 90. The processing block 120 is a part that mainly processes the substrates W, and the indexer block 110 is a part that mainly transports the substrates W between an exterior of the substrate processing apparatus 100 and the processing block 120.

The indexer block 110 includes load ports 111 and an indexer transporter 112. A substrate container (hereinafter referred to as a “carrier”) C is placed on each of the load ports 111. A plurality of the substrates W are housed in the carrier C while being aligned at intervals, for example, in the vertical direction. In the example of FIG. 1, a plurality of the load ports 111 are aligned.

The indexer transporter 112 is a transport robot, and can take unprocessed substrates W from the carrier C placed on each of the load ports 111. The indexer transporter 112 may be referred to as an indexer robot. The indexer transporter 112 transports, to the processing block 120, the unprocessed substrates W which have been taken from the carrier C. The processing block 120 can process the unprocessed substrates W. Furthermore, the indexer transporter 112 can receive the processed substrates W from the processing block 120, and transport the processed substrates W to the carriers C of the load ports 111.

The processing block 120 includes one or more processing modules 1 and a main transporter 80. In the example of FIG. 1, a plurality of the processing modules 1 are provided. The main transporter 80 is a transport robot, and transports the substrates W between the indexer transporter 112 and each of the processing modules 1.

As exemplified in FIG. 1, the processing block 120 may include a transfer part 123. The transfer part 123 relays the substrates W between the indexer transporter 112 and the main transporter 80. For example, the transfer part 123 includes shelves on which the substrates W aligned in the vertical direction can be placed. The indexer transporter 112 places the unprocessed substrates W on the transfer part 123. The main transporter 80 takes the unprocessed substrates W from the transfer part 123, and transports the substrates W to the processing modules 1. The processing modules 1 process the substrates W.

The processing modules 1 may include a dry processing module 1A and a wet processing module 1B as illustrated in FIG. 1, or need not include the wet processing module 1B. When the processing modules 1 include the wet processing module 1B, the main transporter 80 may transport the substrates W from one of the dry processing module 1A and the wet processing module 1B to the other. The dry processing module 1A performs a dry process on the substrates W in a vacuum condition, and the wet processing module 1B performs a wet process on the substrates W in an atmospheric condition. Then, for example, the main transporter 80 transports the substrates W processed by both of the dry processing module 1A and the wet processing module 1B to the transfer part 123.

In the example of FIG. 1, the main transporter 80 is provided in a main transport space TS. The main transport space TS extends along a predetermined movement direction Dx. The movement direction Dx is, for example, a direction along a horizontal direction. In the example of FIG. 1, the movement direction Dx is a direction orthogonal to the alignment direction of the load ports 111. Hereinafter, the horizontal direction orthogonal to the movement direction Dx may be referred to as a width direction Dy (identical to the alignment direction herein). The length of the main transport space TS in the movement direction Dx is larger than the length of the main transport space TS in the width direction Dy. In other words, the main transport space TS has a long shape in the movement direction Dx in a plan view. The plan view herein means viewing a target in a vertical direction.

In the example of FIG. 1, a plurality of the processing modules 1 are provided on one side and the other side of the main transport space TS, with respect to the width direction Dy. In the example of FIG. 1, the plurality (two in FIG. 1) of the processing modules 1 are aligned on each side in the movement direction Dx. In a position where each of the processing modules 1 is provided, a plurality of processing modules 1 may be stacked in the vertical direction. A portion including the plurality of processing modules 1 stacked in the vertical direction will also be referred to as a tower TW.

Each of the processing modules 1 includes a module transport gate GMT. The module transport gate GMT is provided at a boundary between the processing module 1 and the main transport space TS. The module transport gate GMT is an openable and closeable loading/unloading entrance, and its closing and opening is controlled by the controller 90. The module transport gate GMT may be a gate valve or a shutter. This point applies to other gates to be described later. The main transporter 80 stops at a transfer position at which the main transporter 80 faces the module transport gate GMT. Then, the main transporter 80 loads and unloads the substrate W into and out of the processing module 1 through the module transport gate GMT that is opened. An internal space of the processing module 1 is shut off from the main transport space TS while the module transport gate GMT is closed.

The main transporter 80, for example, transports the unprocessed substrates W from the transfer part 123 to the dry processing module 1A. The dry processing module 1A performs the dry process on the substrates W. The dry process is, for example, a process of etching an etching target on the main surface of the substrate W. This dry process sometimes causes impurities to remain on the main surface of the substrate W. The main transporter 80 transports the substrates W that have been subjected to the dry process, from the dry processing module 1A to the wet processing module 1B. Then, the wet processing module 1B performs a wet process on the substrates W that have been subjected to the dry process. The wet process is, for example, a cleaning process of removing impurities on the main surface of the substrate W. This wet process allows removal of at least a part of the impurities on the substrate W. The main transporter 80 transports the substrates W that have been subjected to the wet process, from the wet processing module 1B to the transfer part 123.

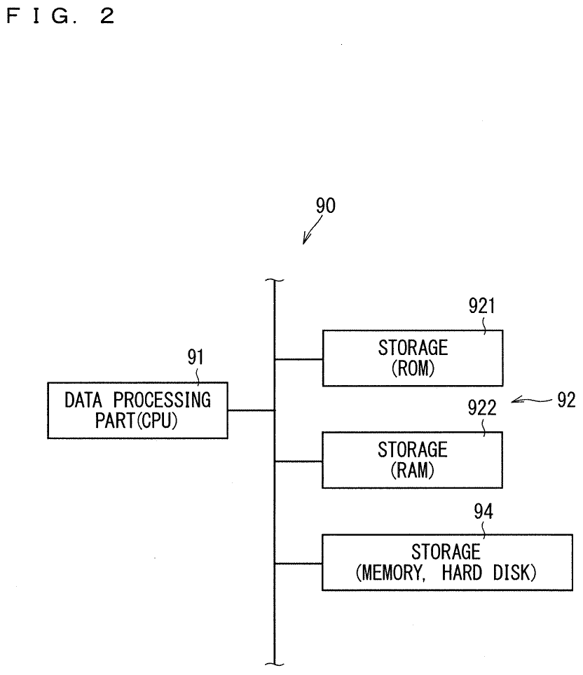

The controller 90 has centralized control over the substrate processing apparatus 100. FIG. 2 schematically illustrating one example internal configuration of the controller 90. The controller 90 is an electronic circuit, and includes, for example, a data processing part 91 and a storage 92. The data processing part 91 and the storage 92 may be mutually connected through a bus. The data processing part 91 may be, for example, an arithmetic processing unit such as a central processing unit (CPU). The storage 92 may include a non-transitory storage (e.g., a read-only memory (ROM)) 921 and a transitory storage (e.g., a random-access memory (RAM)) 922. The non-transitory storage 921 may store, for example, a program for defining processes to be executed by the controller 90. The data processing part 91 executes this program, so that the controller 90 can execute the processes defined in the program. Obviously, hardware such as a dedicated logic circuit may execute a part or all the processes to be executed by the controller 90. In the example of FIG. 2, the controller 90 is also connected to a non-transitory storage 94 (e.g., a memory such as a flash memory or a hard disk).

### [Dry Processing Module]

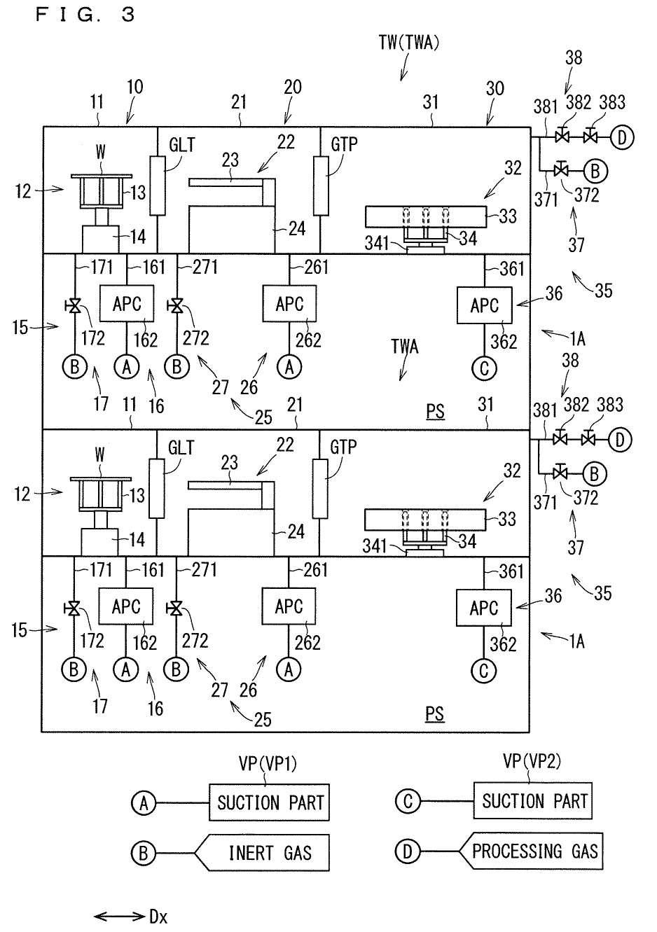

Next, an example structure of the dry processing modules 1A that are essential in Embodiment 1 will be described. FIG. 3 is a vertical cross-sectional view schematically illustrating one example specific structure of the dry processing modules 1A. In the example of FIG. 3, two dry processing modules 1A are stacked in the vertical direction, which will be described later. One example of a structure and operations of each of the dry processing modules 1A will first be outlined and then described in detail later.

As illustrated in FIG. 3, the dry processing module 1A includes a local transport chamber 21 (corresponding to an example upstream chamber), a second pressure regulator 25 (corresponding to an example upstream pressure regulator), a local transporter 22 (corresponding to an example transporter), and a dry processing chamber 31.

The local transport chamber 21 is connected to the dry processing chamber 31 through a transport processing gate GTP (corresponding to an example first gate). In the example of FIG. 3, the dry processing module 1A also includes a load lock chamber 11, and the local transport chamber 21 is connected to the load lock chamber 11 through a load transport gate GLT (corresponding to an example second gate). This point will be described later in detail.

The dry processing chamber 31 forms a dry processing space in which the dry process is performed on the substrate W. The substrate W is subjected to the dry process in the dry processing chamber 31 while the transport processing gate GTP is closed. In the example of FIG. 3, a processing gas supply part 38 for supplying the dry processing chamber 31 with a processing gas is provided. The processing gas supplied to the dry processing chamber 31 acts on the main surface of the substrate W, so that the substrate W is subjected to a dry process corresponding to a type of the processing gas. In the example of FIG. 3, a third pressure regulator 35 (corresponding to an example dry pressure regulator) is also provided. The third pressure regulator 35 regulates a pressure in the dry processing chamber 31 by supplying gas to the dry processing chamber 31 or suctioning gas from the dry processing chamber 31. For example, the third pressure regulator 35 regulates a pressure in the dry processing chamber 31 in a vacuum range. This allows the dry process to be performed on the substrate W in a vacuum condition within the dry processing chamber 31.

The local transporter 22 transports the substrate W between the local transport chamber 21 and the dry processing chamber 31 through the opened transport processing gate GTP. The local transporter 22 also transports the substrate W between the load lock chamber 11 and the local transport chamber 21. This point will be described later in detail.

The second pressure regulator 25 regulates a pressure in the local transport chamber 21 by supplying gas to the local transport chamber 21 or suctioning gas from the local transport chamber 21. For example, the second pressure regulator 25 regulates a pressure in the local transport chamber 21 in a vacuum range. Thus, the local transporter 22 can transport the substrate W between the local transport chamber 21 and the dry processing chamber 31 in a vacuum condition.

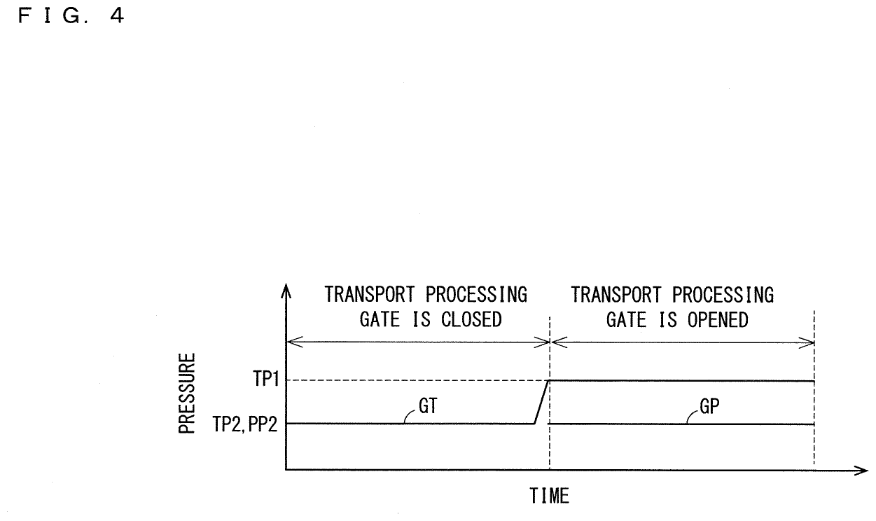

The controller 90 controls the second pressure regulator 25 and the local transporter 22. FIG. 4 illustrates graphs indicating example time variations in the pressure in the local transport chamber 21 and the pressure in the dry processing chamber 31. In the example of FIG. 4, a graph GT indicates the pressure in the local transport chamber 21, and a graph GP indicates the pressure in the dry processing chamber 31. FIG. 4 illustrates the pressures while the load transport gate GLT is closed.

As illustrated in FIG. 4, the pressure in the local transport chamber 21 is higher than the pressure in the dry processing chamber 31 while the transport processing gate GTP is opened. In other words, the controller 90 opens the transport processing gate GTP while controlling the second pressure regulator 25 such that the pressure in the local transport chamber 21 is set to a first transport pressure value TP1 (corresponding to an example first pressure value) higher than the pressure in the dry processing chamber 31. Then, the controller 90 controls the local transporter 22 such that the substrate W is transported between the local transport chamber 21 and the dry processing chamber 31.

Since the pressure in the local transport chamber 21 is higher than the pressure in the dry processing chamber 31 during this transport, gas in the local transport chamber 21 flows into the dry processing chamber 31 through the transport processing gate GTP. Thus, it is possible to reduce the possibility that the gas in the dry processing chamber 31 flows into the local transport chamber 21 through the transport processing gate GTP.

The dry processing chamber 31 may contain impurities such as a by-product generated from a reaction between a processing gas and the substrate W. In Embodiment 1, an inflow of gas from the dry processing chamber 31 into the local transport chamber 21 is prevented as described above. Thus, it is possible to reduce the possibility that the impurities generated by the dry process flow from the dry processing chamber 31 into the local transport chamber 21.

As illustrated in FIG. 4, while the transport processing gate GTP is closed, the controller 90 controls the second pressure regulator 25 such that the pressure in the local transport chamber 21 is reduced to a second transport pressure value TP2 (corresponding to a second pressure value) lower than the first transport pressure value TP1. Even when impurities flows into the local transport chamber 21, the impurities can more reliably be discharged to an exterior. Thus, the internal space of the local transport chamber 21 can be further cleaned.

Next, the specific example of the structure and the operations of the dry processing module 1A will be described in detail. In the examples of FIGS. 1 and 3, the dry processing module 1A also includes the load lock chamber 11. The load lock chamber 11 faces the main transport space TS, and a dry transport gate GDT that is an example of the module transport gate GMT is disposed in a portion facing the main transport space TS. The substrate W is transported between the load lock chamber 11 and the main transporter 80 through the dry transport gate GDT. In other words, the load lock chamber 11 forms an interface space of the dry processing module 1A.

In the examples of FIGS. 1 and 3, the local transporter 22 is disposed in the local transport chamber 21. In other words, the local transport chamber 21 forms a relay space of the substrate W between the load lock chamber 11 and the dry processing chamber 31. The dry processing chamber 31 forms the dry processing space as described above.

A unit to which the load lock chamber 11 belongs will be referred to as a load lock unit 10, a unit to which the local transport chamber 21 belongs will be referred to as a local transport unit 20, and a unit to which the dry processing chamber 31 belongs will be referred to as a dry processing unit 30.

The load lock unit 10 switches between an atmospheric condition and a vacuum condition. In other words, the load lock unit 10 changes a condition of the load lock chamber 11 between an atmospheric condition and a vacuum condition. The main transporter 80 loads and unloads the substrate W into and out of the load lock unit 10 in an atmospheric condition. In other words, the main transporter 80 loads and unloads the substrate W into and out of the load lock chamber 11 in the atmospheric condition through the dry transport gate GDT.

The local transport unit 20 includes the local transporter 22. The local transporter 22 is disposed in the local transport chamber 21. The local transporter 22 is controlled by the controller 90, and transports the substrate W between the load lock unit 10 and the dry processing unit 30 in a vacuum condition.

The dry processing unit 30 performs the dry process on the substrate W in a vacuum condition.

In the examples of FIGS. 1 and 3, the local transport chamber 21 is adjacent to the load lock chamber 11 in the movement direction Dx. Furthermore, in the examples of FIGS. 1 and 3, the dry processing chamber 31 is adjacent to the local transport chamber 21 in the movement direction Dx. In other words, in the examples of FIGS. 1 and 3, the load lock chamber 11, the local transport chamber 21, and the dry processing chamber 31 are aligned in this order in the movement direction Dx. In other words, in the examples of FIGS. 1 and 3, the load lock unit 10 (e.g., the load lock chamber 11), the local transport unit 20 (e.g., the local transport chamber 21), and the dry processing unit 30 (e.g., the dry processing chamber 31) are provided one-to-one in each of the dry processing modules 1A. In other words, the load lock unit 10 and the local transport unit 20 are dedicated units for the single dry processing unit 30.

In this dry processing module 1A, the main transporter 80 loads the unprocessed substrate W into the load lock chamber 11 in an atmospheric condition. Next, the load lock unit 10 reduces the pressure in the load lock chamber 11 in a vacuum range. Then, the local transporter 22 takes the substrate W from the load lock chamber 11 in a vacuum condition, and loads the substrate W into the dry processing chamber 31. The dry processing unit 30 performs the dry process on the substrate W in the dry processing chamber 31. The local transporter 22 takes the substrate W that has been subjected to the dry process from the dry processing chamber 31, and loads the substrate W into the load lock chamber 11. Then, the load lock unit 10 increases the pressure in the load lock chamber 11 into an atmospheric range. Then, the main transporter 80 takes the substrate W out of the load lock chamber 11.

### [Load Lock Unit]

As illustrated in FIG. 3, the load lock unit 10 includes a substrate mounted part 12 and a first pressure regulator 15 besides the load lock chamber 11.

The substrate mounted part 12 is provided within the load lock chamber 11, and supports or holds the substrate W in a horizontal attitude. The horizontal attitude herein is an attitude in which the thickness direction of the substrate W is along the vertical direction. In the example of FIG. 3, the substrate mounted part 12 includes a plurality (e.g., three or more) of support pins 13. Each of the support pins 13 has a rod shape extending in the vertical direction, and its tip is in contact with the lower surface of the substrate W. In this state, the support pins 13 support the substrate W in the horizontal attitude. The substrate mounted part 12 may be a plate-shaped stage that supports the substrate W, or an adsorption stage that adsorptively holds the substrate W. In the example of FIG. 3, the substrate mounted part 12 supports or holds the single substrate W.

As illustrated in FIG. 3, the load lock unit 10 may include a pin lifting driver 14 that lifts and lowers the support pins 13. The pin lifting driver 14 is controlled by the controller 90. For example, the pin lifting driver 14 includes a driving source such as a motor or a pump, and a power transmitter that transmits a driving force of the driving source to the support pins 13. The power transmitter includes, for example, a ball screw mechanism or an air cylinder. The substrate W may be transferred between the support pins 13 and the local transporter 22 by lifting and lowering the support pins 13.

The first pressure regulator 15 regulates a pressure in the load lock chamber 11. For example, the first pressure regulator 15 regulates a pressure in the load lock chamber 11 to a value in the atmospheric range. This creates an atmospheric condition in the load lock chamber 11. The atmospheric range is a range including the standard atmosphere, and may be higher than or equal to 80% of the standard atmosphere and lower than or equal to 120% of the standard atmosphere. Furthermore, the first pressure regulator 15 regulates a pressure in the load lock chamber 11 to a value in a vacuum range lower than the atmospheric range. This creates a vacuum condition in the load lock chamber 11. The vacuum range may be, for example, lower than or equal to one tenth or one hundredth of the standard atmosphere.

In the example of FIG. 3, the first pressure regulator 15 includes a first gas suction part 16 and a first gas supply part 17. The first gas supply part 17 supplies gas to the load lock chamber 11. The gas is, for example, an inert gas. The inert gas includes, for example, at least one of a noble gas and a nitrogen gas. The noble gas includes, for example, at least one of an argon gas and a neon gas. The first gas suction part 16 suctions gas from the load lock chamber 11.

In the example of FIG. 3, the first gas supply part 17 includes a first supply pipe 171 and a first supply valve 172. A downstream end of the first supply pipe 171 is connected to, for example, a bottom of the load lock chamber 11. An upstream end of the first supply pipe 171 is connected to an inert gas supply source. The inert gas supply source includes a reservoir (not illustrated) that reserves the inert gas. The first supply valve 172 is disposed in the first supply pipe 171. The first supply valve 172 is controlled by the controller 90, and switches between closing and opening of the first supply pipe 171.

In the example of FIG. 3, the first gas suction part 16 includes a first suction pipe 161, a first pressure regulating valve 162, and a suction part VP. An upstream end of the first suction pipe 161 is connected to, for example, the bottom of the load lock chamber 11. A downstream end of the first suction pipe 161 is connected to the suction part VP. The suction part VP is, for example, a pump, and is controlled by the controller 90. The suction part VP suctions gas in the load lock chamber 11 through the first suction pipe 161. The first pressure regulating valve 162 is disposed in the first suction pipe 161. The first pressure regulating valve 162 is controlled by the controller 90. The first pressure regulating valve 162 regulates a pressure in the load lock chamber 11 by regulating its degree of opening. The first pressure regulating valve 162 is, for example, an auto pressure controller. The first pressure regulating valve 162 may include a pressure sensor, or a pressure sensor may be disposed in the load lock chamber 11. The first pressure regulating valve 162 regulates the degree of opening according to a detection value of the pressure sensor, so that a pressure in the load lock chamber 11 can be regulated with higher accuracy. The same applies to other pressure regulating valves to be describe later.

The dry transport gate GDT and the load transport gate GLT of the load lock chamber 11 are openable and closeable loading/unloading entrances, and are controlled by the controller 90. The dry transport gate GDT is opened and closed while the pressure in the load lock chamber 11 is in the atmospheric range. The main transporter 80 loads and unloads the substrate W into and out of the load lock chamber 11 through the dry transport gate GDT while the dry transport gate GDT is open. The load transport gate GLT is opened and closed while the pressure in the load lock chamber 11 and the pressure in the local transport chamber 21 are in a vacuum range. The local transporter 22 loads and unloads the substrate W into and out of the load lock chamber 11 through the load transport gate GLT while the load transport gate GLT is open.

### [Local Transport Unit]

The local transport unit 20 includes the second pressure regulator 25, besides the local transport chamber 21 and the local transporter 22.

The local transporter 22 is a transport robot, and is controlled by the controller 90. In the example of FIG. 3, the local transporter 22 includes a hand 23 and a hand movement driver 24. The hand 23 is, for example, plate-shaped. The hand 23 holds or supports the substrate W in a horizontal attitude. For example, the substrate W is placed on the hand 23. The hand movement driver 24 is controlled by the controller 90, and moves the hand 23. For example, the hand movement driver 24 includes a driving source such as a motor, and a power transmitter that transmits a driving force of the driving source to the hand 23. The power transmitter includes, for example, at least one of an arm mechanism, a ball screw mechanism, a rotation mechanism, and a cam mechanism.

The second pressure regulator 25 regulates a pressure in the local transport chamber 21. Specifically, the second pressure regulator 25 regulates a pressure in the local transport chamber 21 to a value in a vacuum range. This creates a vacuum condition in the local transport chamber 21. The second pressure regulator 25 includes a second gas suction part 26 and a second gas supply part 27. The second gas supply part 27 supplies gas (e.g., an inert gas) to the local transport chamber 21. The second gas suction part 26 suctions gas from the local transport chamber 21. In the example of FIG. 3, the second gas supply part 27 includes a second supply pipe 271 (corresponding to an example supply pipe) and a second supply valve 272 (corresponding to an example supply valve). The second gas suction part 26 includes a second suction pipe 261 (corresponding to an example suction pipe), a second pressure regulating valve 262 (corresponding to an example pressure regulating valve), and the suction part VP. Since the structure of these is identical to that of the first pressure regulator 15, the detailed description will be omitted.

The transport processing gate GTP is an openable and closeable loading/unloading entrance, and is controlled by the controller 90. The transport processing gate GTP is opened and closed while the pressure in the local transport chamber 21 and the pressure in the dry processing chamber 31 are in a vacuum range. The local transporter 22 loads and unloads the substrate W into and out of the dry processing chamber 31 through the transport processing gate GTP while the transport processing gate GTP is open.

### [Dry Processing Unit]

The dry processing unit 30 includes a substrate mounted part 32, the third pressure regulator 35, and the processing gas supply part 38, besides the dry processing chamber 31.

The substrate mounted part 32 is provided within the dry processing chamber 31, and supports or holds the substrate W in a horizontal attitude. In the example of FIG. 3, the substrate mounted part 32 includes a stage 33 and a plurality of lift pins 34. The stage 33 is plate-shaped, and is disposed in an attitude such that its thickness direction is along the vertical direction. The substrate W is placed on the stage 33 in a horizontal attitude.

The lift pins 34 have a rod shape extending in the vertical direction, and at least a part of the lift pins 34 are disposed to penetrate the stage 33. A pin lifting driver 341 lifts and lowers the lift pins 34 between a first height position and a second height position. The first height position is a position at which tips of the lift pins 34 are higher than the upper surface of the stage 33, and the second height position is a position at which the tips of the lift pins 34 are lower than the upper surface of the stage 33. The pin lifting driver 341 is controlled by the controller 90. For example, the pin lifting driver 341 includes a driving source such as a motor or a pump, and a power transmitter that transmits a driving force of the driving source to the lift pins 34. The power transmitter includes, for example, a ball screw mechanism or an air cylinder. The substrate W can be transferred between the stage 33 and the local transporter 22 by lifting and lowering the lift pins 34.

The third pressure regulator 35 regulates a pressure in the dry processing chamber 31. Specifically, the third pressure regulator 35 regulates the pressure in the dry processing chamber 31 to a value in a vacuum range. This creates a vacuum condition in the dry processing chamber 31. The third pressure regulator 35 includes a third gas suction part 36 and a third gas supply part 37. The third gas supply part 37 supplies gas (e.g., an inert gas) to the dry processing chamber 31. The third gas suction part 36 suctions gas from the dry processing chamber 31. In the example of FIG. 3, the third gas supply part 37 includes a third supply pipe 371 and a third supply valve 372. The third gas suction part 36 includes a third suction pipe (corresponding to an example third gas pipe) 361, a third pressure regulating valve 362, and the suction part VP. Since the structure of these is identical to that of the first pressure regulator 15, the detailed description will be omitted. In the example of FIG. 3, a downstream end of the third supply pipe 371 is connected to a side of the dry processing chamber 31.

The processing gas supply part 38 supplies the dry processing chamber 31 with a processing gas. The processing gas acts on the main surface (the upper surface herein) of the substrate W placed on the substrate mounted part 32 (specifically, the stage 33). Consequently, the main surface of the substrate W is subjected to a dry process corresponding to a type of the processing gas. For example, the processing gas is an etching gas. The etching gas removes an etching target of the substrate W. Specific examples of the processing gas include hydrogen fluoride gas, and may further include steam. Hydrogen fluoride gas (further steam) acts on an oxide film (e.g., a silicon oxide film) of the substrate W, so that the oxide film can be etched. This dry process may cause a component (e.g., fluorine) of the processing gas, a by-product, or a residue of an etching target to remain on the main surface of the substrate W.

In the example of FIG. 3, the processing gas supply part 38 includes a supply pipe 381, a supply valve 382, and a flow rate regulation valve 383. A downstream end of the supply pipe 381 is connected to, for example, the side of the dry processing chamber 31. In the example of FIG. 3, the supply pipe 381 and the third supply pipe 371 merge into a common pipe, and a downstream end of the common pipe is connected to the side of the dry processing chamber 31. An upstream end of the supply pipe 381 is connected to a processing gas supply source. The processing gas supply source includes a reservoir (not illustrated) that reserves the processing gas. The supply valve 382 and the flow rate regulation valve 383 are disposed in the supply pipe 381. The supply valve 382 is controlled by the controller 90, and switches between closing and opening of the supply pipe 381. The flow rate regulation valve 383 is controlled by the controller 90, and regulates a flow rate of the processing gas flowing through the supply pipe 381. When the processing gas includes gases of a plurality of types, the supply pipe 381, the supply valve 382, and the flow rate regulation valve 383 may be provided for each of the types.

The dry processing unit 30 may include a plasma reactor that forms the processing gas into a plasma. The plasma reactor may be, for example, a capacitively coupled or inductively coupled plasma reactor. The dry processing unit 30 may apply a plasma treatment to the substrate W by causing various active species (e.g., ion or radical) included in the plasma to act on the main surface of the substrate W.

### [Pressure Control in Dry Processing Module]

Next, example pressure control in the dry processing module 1A will be described. The pressure in the local transport chamber 21 and the pressure in the dry processing chamber 31 are already described with reference to FIG. 4.

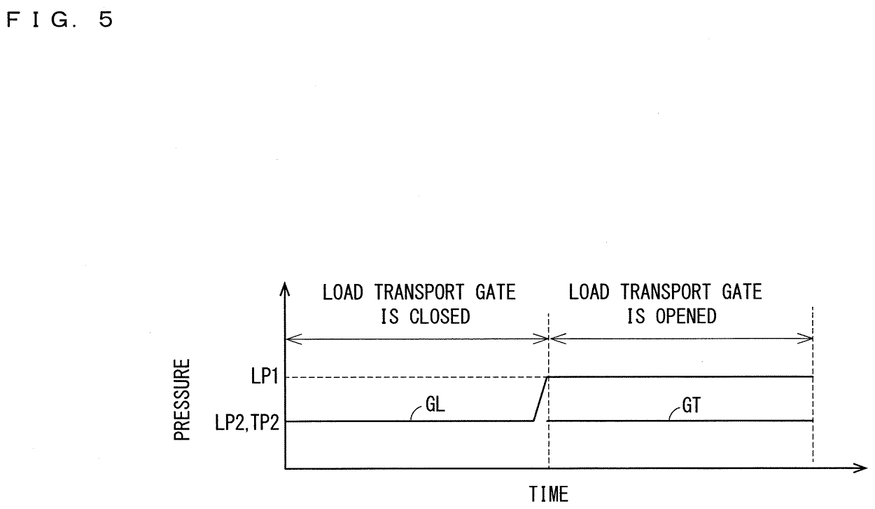

Next, the pressure in the load lock chamber 11 and the pressure in the local transport chamber 21 will be described. FIG. 5 illustrates graphs indicating example time variations in the pressure in the load lock chamber 11 and the pressure in the local transport chamber 21. In the example of FIG. 5, a graph GL indicates the pressure in the load lock chamber 11, and a graph GT indicates the pressure in the local transport chamber 21. FIG. 5 illustrates the pressures while the transport processing gate GTP and the dry transport gate GDT are closed.

In the example of FIG. 5, the pressure in the load lock chamber 11 is higher than the pressure in the local transport chamber 21 while the load transport gate GLT is opened. In other words, the controller 90 opens the load transport gate GLT while controlling the first pressure regulator 15 such that the pressure in the load lock chamber 11 is set to a first load pressure value LP1 higher than the pressure in the local transport chamber 21. Then, the controller 90 controls the local transporter 22 such that the substrate W is transported between the load lock unit 10 and the local transport unit 20 through the load transport gate GLT.

Thus, it is possible to reduce the possibility that the gas in the local transport chamber 21 flows into the load lock chamber 11. Thus, even when impurities from the dry processing chamber 31 slightly remain in the local transport chamber 21, the possibility that the impurities flow into the load lock chamber 11 can be reduced.

As exemplified in FIG. 5, the controller 90 may control the first pressure regulator 15 such that the pressure in the load lock chamber 11 is regulated to a second load pressure value LP2 lower than the first load pressure value LP1 while the load transport gate GLT is closed. Even when impurities slightly flow into the load lock chamber 11, the impurities can more reliably be discharged to an exterior through the first suction pipe 161. Thus, the internal space of the load lock chamber 11 can be further cleaned.

Consequently, it is possible to reduce the possibility that the impurities flow from the load lock chamber 11 into the main transport space TS, and the possibility that the impurities flow into the other processing modules 1.

### [Operations of Dry Processing Module 1A]

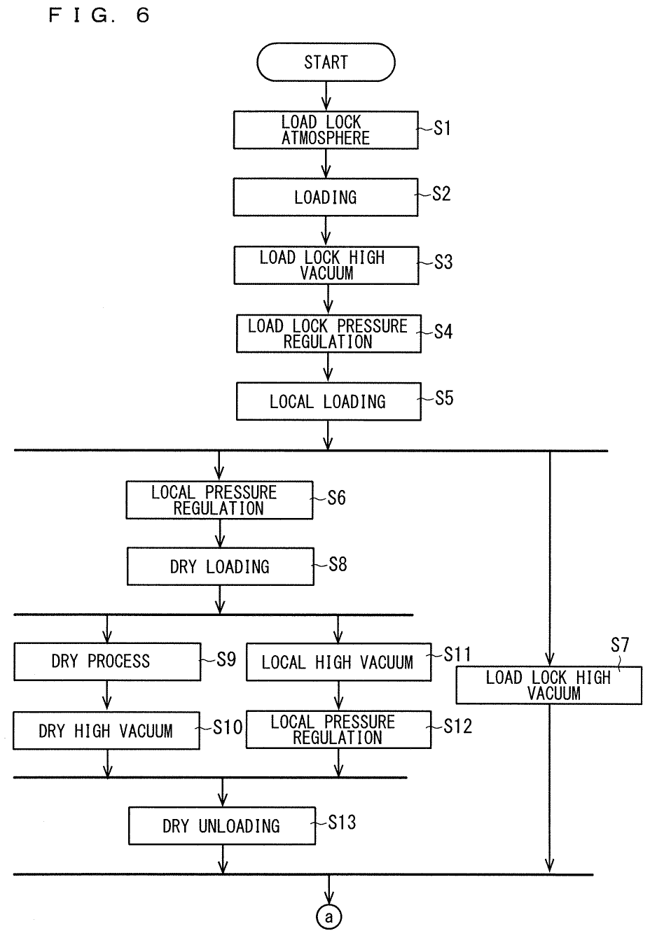

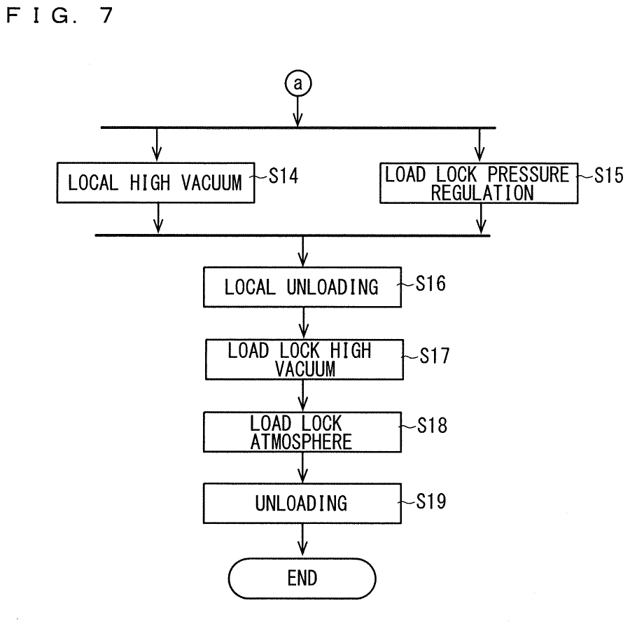

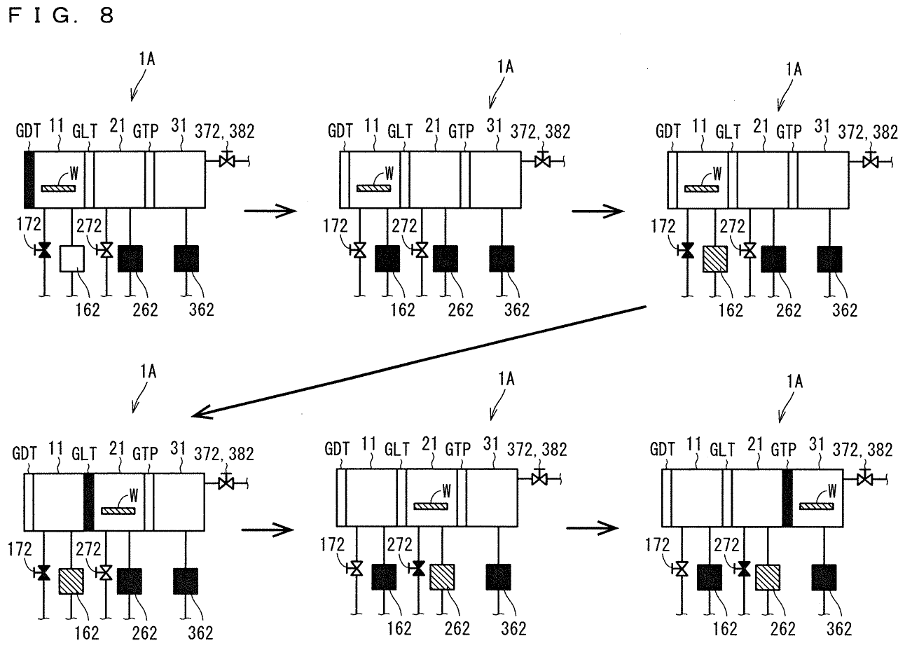

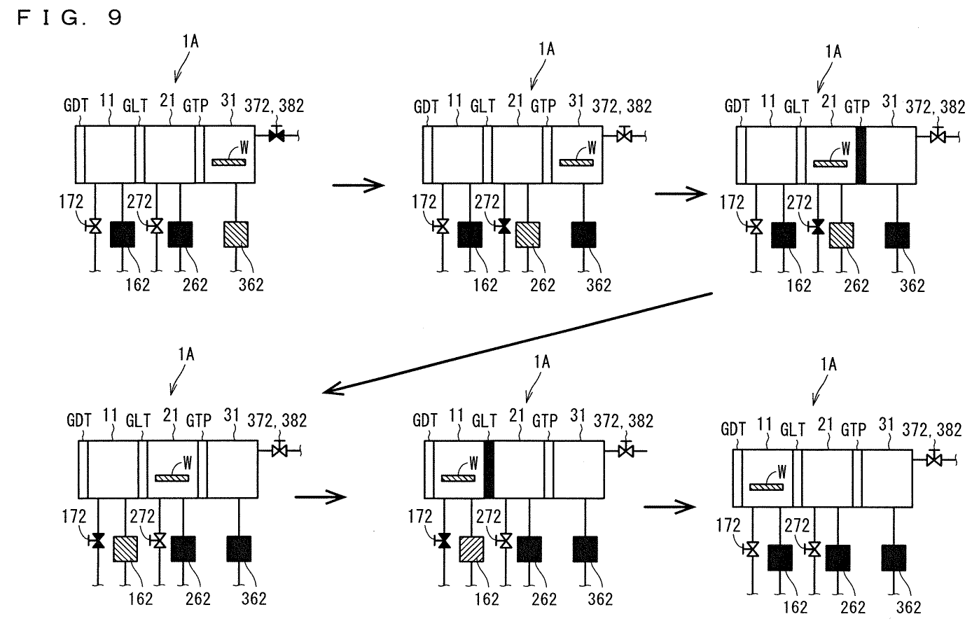

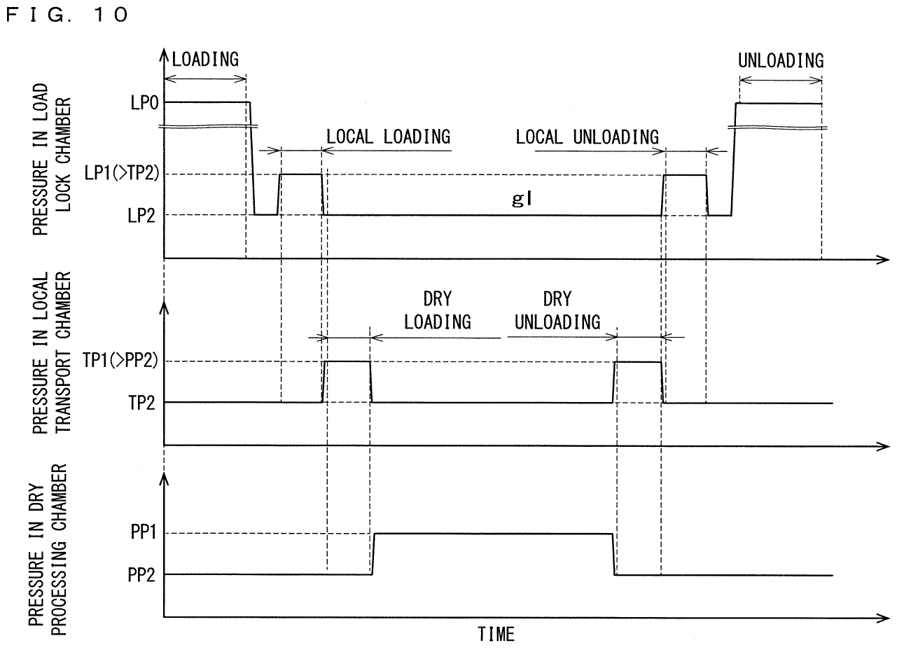

FIGS. 6 and 7 are flowcharts illustrating example operations of the dry processing module 1A. FIGS. 8 and 9 are diagram schematically illustrating example state changes during operations of the dry processing module 1A according to Embodiment 1. FIG. 10 is a diagram illustrating example time variations in the pressures in the load lock chamber 11, the local transport chamber 21, and the dry processing chamber 31.

Initially, the load lock chamber 11, the local transport chamber 21, and the dry processing chamber 31 are sealed. In other words, the controller 90 closes the dry transport gates GDT, the load transport gates GLT, and the transport processing gates GTP.

First, the controller 90 controls the first pressure regulator 15 such that the pressure in the load lock chamber 11 is regulated to a value in an atmospheric range (hereinafter referred to as an atmospheric value LP0) (Step S1). For example, the controller 90 opens the first supply valve 172, and closes the first pressure regulating valve 162. In the examples of FIGS. 8 and 9, opened valves are illustrated in black. The atmospheric value LP0 may be a value as large as the standard atmosphere.

In the example of FIG. 10, the pressure in the local transport chamber 21 is initially regulated to the second transport pressure value TP2. The second transport pressure value TP2 is a value in a vacuum range, and may be, for example, a value lower than or equal to one one-thousandth or one two-thousandth of the standard atmosphere. As a specific example, the second transport pressure value TP2 may be 6 Pa or higher and 90 Pa or lower, or 6 Pa or higher and 50 Pa or lower. For example, the controller 90 may herein control the second pressure regulator 25 as follows. In other words, the controller 90 may close the second supply valve 272, and open the second pressure regulating valve 262 at a predetermined second degree of opening (will be described later).

In the example of FIG. 10, the pressure in the dry processing chamber 31 is initially regulated to a second dry pressure value PP2. The second dry pressure value PP2 is a value in the vacuum range, and may be, for example, a value lower than or equal to one one-thousandth or one two-thousandth of the standard atmosphere. As a specific example, the second dry pressure value PP2 may be 6 Pa or higher and 90 Pa or lower, or 6 Pa or higher and 50 Pa or lower. Here, the controller 90 may control the third pressure regulator 35 as follows. In other words, the controller 90 may close the third supply valve 372 and the supply valve 382, and open the third pressure regulating valve 362 at a predetermined third degree of opening (will be described later).

Next, the controller 90 opens the dry transport gate GDT, and controls the main transporter 80 such that the substrate W is loaded into the load lock chamber 11 (Step S2). Consequently, the support pins 13 support the substrate W. In the examples of FIGS. 8 and 9, opened gates are illustrated in black. The controller 90 closes the dry transport gate GDT after the loading.

Next, the controller 90 may control the first pressure regulator 15 such that the pressure in the load lock chamber 11 is temporarily regulated to the second load pressure value LP2 (Step S3, see also FIG. 10). The second load pressure value LP2 is a value in a vacuum range, and may be, for example, a value lower than or equal to one one-thousandth or one two-thousandth of the standard atmosphere. As a specific example, the second load pressure value LP2 may be 6 Pa or higher and 90 Pa or lower, or 6 Pa or higher and 50 Pa or lower. Thus, the internal space of the load lock chamber 11 can be further cleaned.

In this Step S3, the controller 90 may close the first supply valve 172 as illustrated in the upper middle of FIG. 8. This can reduce the consumption of the inert gas. In Step S3, the controller 90 may maintain the first pressure regulating valve 162, for example, at a predetermined first degree of opening. Since the degree of opening of the first pressure regulating valve 162 is not dynamically regulated, the power consumption can be reduced. Furthermore, the life of the first pressure regulating valve 162 can be extended. The predetermined first degree of opening may be larger than or equal to a degree of opening of the first pressure regulating valve 162 in Step S4 that will be described later, or larger than the degree of opening of the first pressure regulating valve 162. As a specific example, the predetermined first degree of opening may be a fully open position. This can reduce the pressure in the load lock chamber 11 to the second load pressure value LP2 more promptly.

Next, the controller 90 controls the first pressure regulator 15 such that the pressure in the load lock chamber 11 is increased to the first load pressure value LP1 (Step S4, see also FIG. 10). The first load pressure value LP1 is a value in a vacuum range, and higher than the pressure in the local transport chamber 21. Since the pressure in the local transport chamber 21 is the second transport pressure value TP2, the first load pressure value LP1 is higher than the second transport pressure value TP2. A difference between the first load pressure value LP1 and the second transport pressure value TP2 may be, for example, 10 Pa or higher. The first load pressure value LP1 is, for example, 1000 Pa or lower.

In this Step S4, the controller 90 opens the first supply valve 172 such that the inert gas is supplied to the load lock chamber 11, and also controls the first pressure regulating valve 162 as illustrated in the upper right of FIG. 8. The first pressure regulating valve 162 dynamically regulates the degree of opening according to the pressure in the load lock chamber 11. This allows the first pressure regulator 15 to regulate the pressure in the load lock chamber 11 to the first load pressure value LP1 with higher accuracy. In the examples of FIGS. 8 and 9, pressure regulating valves each dynamically regulating a degree of opening according to a pressure are diagonally hatched.

Next, the dry processing module 1A transports the substrate W from the load lock unit 10 to the local transport unit 20 (Step S5). Specifically, the controller 90 first opens the load transport gate GLT. Then, the controller 90 controls the pin lifting driver 14 and the local transporter 22 such that the substrate W is loaded from the load lock chamber 11 into the local transport chamber 21 through the load transport gate GLT. For example, the controller 90 controls the pin lifting driver 14 such that the support pins 13 are lifted, and controls the local transporter 22 such that the hand 23 is moved immediately below the substrate W. Next, the controller 90 controls the pin lifting driver 14 such that the support pins 13 are lowered. This passes the substrate W to the hand 23. Next, the controller 90 controls the local transporter 22 such that the hand 23 is moved inside the local transport chamber 21. Consequently, the substrate W is loaded into the local transport chamber 21 as illustrated in the lower left of FIG. 8. Then, the controller 90 closes the load transport gate GLT.

During this transport, the pressure in the load lock chamber 11 is higher than the pressure in the local transport chamber 21. For example, the first pressure regulator 15 continues to regulate the pressure in the load lock chamber 11 to the first load pressure value LP1 at least over the entire period during which the load transport gate GLT is opened. Thus, the gas in the load lock chamber 11 flows into the local transport chamber 21 through the load transport gate GLT. Conversely speaking, it is possible to reduce the possibility that the gas in the local transport chamber 21 flows into the load lock chamber 11 through the load transport gate GLT.

Next, the controller 90 controls the second pressure regulator 25 such that the pressure in the local transport chamber 21 is increased to the first transport pressure value TP1 (Step S6, see also FIG. 10). The first transport pressure value TP1 is a value in a vacuum range, and higher than the pressure in the dry processing chamber 31. Since the pressure in the dry processing chamber 31 is the second dry pressure value PP2, the first transport pressure value TP1 is higher than the second dry pressure value PP2. A difference between the first transport pressure value TP1 and the second dry pressure value PP2 may be, for example, 10 Pa or higher. The first transport pressure value TP1 may be, for example, 1000 Pa or higher.

In this Step S6, the controller 90 opens the second supply valve 272 to supply the inert gas to the local transport chamber 21, and also controls the second pressure regulating valve 262 as illustrated in the lower middle of FIG. 8. The second pressure regulating valve 262 dynamically regulates the degree of opening according to the pressure in the local transport chamber 21. This can regulate the pressure in the local transport chamber 21 to the first transport pressure value TP1 with higher accuracy.

On the other hand, the controller 90 may control the first pressure regulator 15 such that the pressure in the load lock chamber 11 is reduced to the second load pressure value LP2, after the load transport gate GLT is closed (Step S7, see also FIG. 10). Thus, the internal space of the load lock chamber 11 can be further cleaned. As illustrated in the lower middle of FIG. 8, the controller 90 may close the first supply valve 172 similarly to Step S3, and maintain the degree of opening of the first pressure regulating valve 162, for example, at the predetermined first degree of opening (e.g., a fully open position). The second pressure regulator 25 may regulate the pressure in the load lock chamber 11 to the second load pressure value LP2 until Step S15 that will be described later.

After Step S6, the dry processing module 1A transports the substrate W from the local transport unit 20 to the dry processing unit 30 (Step S8: corresponding to an example of a first step). Specifically, the controller 90 first opens the transport processing gate GTP. Then, the controller 90 controls the local transporter 22 and the pin lifting driver 341 such that the substrate W is passed from the local transport unit 20 to the dry processing unit 30 through the transport processing gate GTP. For example, the controller 90 controls the local transporter 22 such that the hand 23 is moved immediately above the lift pins 34, and then controls the pin lifting driver 341 such that the lift pins 34 are lifted. Consequently, the substrate W is passed to the lift pins 34. Next, the controller 90 controls the local transporter 22 such that the hand 23 is moved inside the local transport chamber 21, and controls the pin lifting driver 341 such that the lift pins 34 are lowered. This passes the substrate W to the stage 33. In other words, the substrate W is loaded into the dry processing chamber 31 as illustrated in the lower right of FIG. 8. Then, the controller 90 closes the transport processing gate GTP.

During this transport, the pressure in the local transport chamber 21 is higher than the pressure in the dry processing chamber 31. For example, the second pressure regulator 25 continues to regulate the pressure in the local transport chamber 21 to the first transport pressure value TP1 at least over the entire period during which the transport processing gate GTP is opened. Thus, the gas in the local transport chamber 21 flows into the dry processing chamber 31 through the transport processing gate GTP. Conversely speaking, it is possible to reduce the possibility that the gas in the dry processing chamber 31 flows into the local transport chamber 21 through the transport processing gate GTP.

Next, the controller 90 controls the third pressure regulator 35 such that the pressure in the dry processing chamber 31 is regulated to a first dry pressure value PP1 (Step S9, see also FIG. 10). The first dry pressure value PP1 is higher than the second dry pressure value PP2, and is a value within a pressure range appropriate for the dry process. The first dry pressure value PP1 is a value in a vacuum range, and may be, for example, approximately 1000 Pa or lower. Here, the controller 90 opens the third supply valve 372 to supply the inert gas to the dry processing chamber 31, and also controls the third pressure regulating valve 362 such that the pressure in the dry processing chamber 31 is regulated to the first dry pressure value PP1 as illustrated in the upper left of FIG. 9. The third pressure regulating valve 362 regulates a degree of opening according to the pressure in the dry processing chamber 31. This allows the third pressure regulating valve 362 to regulate the pressure in the dry processing chamber 31 to the first dry pressure value PP1 with higher accuracy.

When the pressure in the dry processing chamber 31 becomes the first dry pressure value PP1, the controller 90 controls the processing gas supply part 38 such that the processing gas is supplied to the dry processing chamber 31. Specifically, the controller 90 opens the supply valve 382. Once the supply valve 382 is opened, the processing gas is supplied to the dry processing chamber 31 to act on the main surface of the substrate W. Consequently, the main surface of the substrate W is subjected to the dry process corresponding to the type of the processing gas.

After the dry process has been sufficiently performed, the controller 90 controls the processing gas supply part 38 such that supply of the processing gas is stopped. For example, the controller 90 may measure an elapsed time since start of supplying the processing gas. For example, a timer circuit (not illustrated) belonging to the controller 90 performs this measurement. When the elapsed time exceeds a predetermined dry processing time, the controller 90 may stop supplying the processing gas.

This dry process can process the main surface of the substrate W. On the other hand, this dry process creates, in the dry processing chamber 31, impurities such as a by-product of the substrate W and the processing gas.

At the end of the dry process, the controller 90 controls the third pressure regulator 35 such that the pressure in the dry processing chamber 31 is regulated to the second dry pressure value PP2 (Step S10, see also FIG. 10). This allows many more impurities in the dry processing chamber 31 to be discharged to an exterior through a third suction pipe 361. Thus, the internal space of the dry processing chamber 31 can be further cleaned. For example, in Step S10, the controller 90 may close the third supply valve 372 as illustrated in the upper middle of FIG. 9. This can reduce the usage of the inert gas. Furthermore, in Step S10, the controller 90 may maintain the degree of opening of the third pressure regulating valve 362 at the predetermined third degree of opening. This can reduce the power consumption, and extend the life of the third pressure regulating valve 362. The predetermined third degree of opening may be larger than or equal to a degree of opening of the third pressure regulating valve 362 in Step S9, or larger than the degree of opening of the third pressure regulating valve 362. As a specific example, the predetermined third degree of opening may be a fully open position. This can reduce the pressure in the dry processing chamber 31 to the second dry pressure value PP2 more promptly.

After the transport processing gate GTP is closed, the controller 90 controls the second pressure regulator 25 such that the pressure in the local transport chamber 21 is temporarily reduced to the second transport pressure value TP2 (Step S11: corresponding to an example of the second step, see also FIG. 10). Thus, the internal space of the local transport chamber 21 can be further cleaned. For example, in Step S11, the controller 90 may close the second supply valve 272 as illustrated in the upper left of FIG. 9, or maintain the second pressure regulating valve 262, for example, at a predetermined second degree of opening. In other words, the controller 90 may close the second supply valve 272 and maintain the second pressure regulating valve 262 at the second degree of opening such that the pressure in the local transport chamber 21 is reduced to the second transport pressure value TP2. The usage of the inert gas can be reduced by closing the second supply valve 272. The power consumption can be reduced and the life of the second pressure regulating valve 262 can be extended, by maintaining the degree of opening of the second pressure regulating valve 262. The predetermined second degree of opening may be larger than or equal to the degree of opening of the second pressure regulating valve 262 in Step S6, or larger than the degree of opening of the second pressure regulating valve 262. As a specific example, the predetermined second degree of opening may be a fully open position. This can reduce the pressure in the local transport chamber 21 to the second transport pressure value TP2 more promptly.

Next, the controller 90 controls the second pressure regulator 25 such that the pressure in the local transport chamber 21 is regulated to the first transport pressure value TP1 (Step S12, see FIG. 10). For example, the controller 90 opens the second supply valve 272 and controls the second pressure regulating valve 262 similarly to Step S6, as illustrated in the upper middle of FIG. 9. Although there is no particular start trigger of Step S12, for example, the trigger may be stopping supply of a processing gas to the dry processing chamber 31.

After Step S10 and Step S12, the dry processing module 1A transports the substrate W from the dry processing unit 30 to the local transport unit 20 (Step S13: corresponding to the example of the first step). Specifically, the controller 90 first opens the transport processing gate GTP. Then, the controller 90 controls the local transporter 22 and the pin lifting driver 341 such that the substrate W is loaded from the dry processing chamber 31 into the local transport chamber 21 through the transport processing gate GTP. For example, the controller 90 controls the pin lifting driver 341 such that the lift pins 34 are lifted. Consequently, the stage 33 passes the substrate W to the lift pins 34. Next, the controller 90 controls the local transporter 22 such that the hand 23 is moved immediately below the substrate W, and then controls the pin lifting driver 341 such that the lift pins 34 are lowered. Consequently, the substrate W is passed to the hand 23 of the local transporter 22. Next, the controller 90 controls the local transporter 22 such that the hand 23 is moved within the local transport chamber 21. Consequently, the substrate W is transported into the local transport chamber 21 as illustrated in the upper right of FIG. 9. Then, the controller 90 closes the transport processing gate GTP.

During this transport, the pressure in the local transport chamber 21 is higher than the pressure in the dry processing chamber 31. For example, the second pressure regulator 25 continues to regulate the pressure in the local transport chamber 21 to the first transport pressure value TP1 at least over the entire period during which the transport processing gate GTP is opened. Thus, it is possible to reduce the possibility that the gas in the dry processing chamber 31 flows into the local transport chamber 21.

Next, the controller 90 controls the second pressure regulator 25 such that the pressure in the local transport chamber 21 is regulated to the second transport pressure value TP2 (Step S14: corresponding to the example of the second step, see also FIG. 10). For example, the controller 90 may close the second supply valve 272, or maintain the second pressure regulating valve 262 at the predetermined second degree of opening (e.g., a fully open position) similarly to Step S11, as illustrated in the lower left of FIG. 9. Since the pressure in the local transport chamber 21 is regulated to the smaller second transport pressure value TP2, even when impurities slightly flow into the local transport chamber 21, many more impurities can be discharged to an exterior through the second suction pipe 261. Thus, the internal space of the local transport chamber 21 can be further cleaned.

Furthermore, the controller 90 controls the first pressure regulator 15 such that the pressure in the load lock chamber 11 is regulated to the first load pressure value LP1 (Step S15, see also FIG. 10). For example, the controller 90 opens the first supply valve 172 and controls the first pressure regulating valve 162, similarly to Step S4 as illustrated in the lower left of FIG. 9. Although there is no particular start trigger of Step S15, for example, the trigger may be closing the transport processing gate GTP.

Next, the dry processing module 1A transports the substrate W from the local transport unit 20 to the load lock unit 10 (Step S16). Specifically, the controller 90 first opens the load transport gate GLT. Then, the controller 90 controls the local transporter 22 and the pin lifting driver 14 such that the substrate W is loaded from the local transport chamber 21 into the load lock chamber 11 through the load transport gate GLT. For example, the controller 90 controls the local transporter 22 such that the hand 23 is moved immediately above the support pins 13, and then controls the pin lifting driver 14 such that the support pins 13 are lifted. This passes the substrate W to the support pins 13. Next, the controller 90 controls the local transporter 22 such that the hand 23 is moved within the local transport chamber 21. Consequently, the substrate W is transported into the load lock chamber 11 as illustrated in the lower middle of FIG. 9. Then, the controller 90 closes the load transport gate GLT.

During this transport, the pressure in the load lock chamber 11 is higher than the pressure in the local transport chamber 21. For example, the first pressure regulator 15 continues to regulate the pressure in the load lock chamber 11 to the first transport pressure value TP1 at least over the entire period during which the load transport gate GLT is opened. Thus, it is possible to reduce the possibility that the gas in the local transport chamber 21 flows into the load lock chamber 11. In other words, it is possible to reduce the possibility that the gas in the dry processing chamber 31 flows into the load lock chamber 11 through the local transport chamber 21.

Next, the controller 90 may control the first pressure regulator 15 such that the pressure in the load lock chamber 11 is temporarily regulated to the second load pressure value LP2 (Step S17, see also FIG. 10). For example, the controller 90 may close the first supply valve 172 and maintain the first pressure regulating valve 162 at the predetermined first degree of opening (e.g., a fully open position), similarly to Step S3 as illustrated in the lower right of FIG. 9. Since the pressure in the load lock chamber 11 is regulated to the smaller second load pressure value LP2, even when impurities slightly flow into the load lock chamber 11, many more impurities can be discharged to an exterior through the first suction pipe 161. Thus, the internal space of the load lock chamber 11 can be further cleaned.

Next, the controller 90 controls the first pressure regulator 15 such that the pressure in the load lock chamber 11 is regulated to the atmospheric value LP0 (Step S18, see also FIG. 10). Step S17 is identical to Step S1.

Next, the controller 90 opens the module transport gate GMT, and control the main transporter 80 such that the substrate W is passed from the load lock unit 10 to the main transporter 80 (Step S19).

As described above, the transport processing gate GTP is opened while the pressure in the local transport chamber 21 is set to the first transport pressure value TP1 higher than the pressure in the dry processing chamber 31 in Embodiment 1 (Step S8 and Step S13). Thus, it is possible to reduce the possibility that the gas and impurities in the dry processing chamber 31 flow into the local transport chamber 21. Consequently, the possibility of contaminating the substrate W can be reduced.

While the transport processing gate GTP is closed, the second pressure regulator 25 reduces the pressure in the local transport chamber 21 to the second transport pressure value TP2 lower than the first transport pressure value TP1 (Step S11 and Step S14). This allows many more impurities to more reliably be discharged from the local transport chamber 21, even when impurities slightly flow from the dry processing chamber 31 into the local transport chamber 21. Thus, the internal space of the local transport chamber 21 can be further cleaned.

This is particularly effective when the local transport chamber 21 is provided one-to-one with the dry processing chamber 31. Here, a structure in which the local transport chamber 21 is connected to a plurality of dry processing chambers 31 will be considered. In this structure, the local transporter 22 sequentially loads and unloads the substrates W into and out of the plurality of dry processing chambers 31. Even while one of the dry processing chambers 31 is performing the dry process, once another dry processing chamber 31 ends the dry process, the local transport chamber 21 communicates with the other dry processing chamber 31 to load and unload the substrates W. Thus, the shielding time during which the local transport chamber 21 is shielded from the internal space of all the dry processing chambers 31 is relatively short. For example, the shielding time is much shorter than the dry processing time. Thus, it is difficult to sufficiently reduce the pressure in the local transport chamber 21 during the shielding time. Consequently, it is difficult to sufficiently clean the internal space of the local transport chamber 21.

In contrast, when the local transport chamber 21 is provided one-to-one with the dry processing chamber 31, the local transport chamber 21 is shielded from the dry processing chamber 31 during the dry process of the dry processing chamber 31. Thus, the shielding time is longer than or equal to the dry processing time. Consequently, it is possible to sufficiently reduce the pressure in the local transport chamber 21 during the shielding time. Thus, the internal space of the local transport chamber 21 can be further cleaned.

In the aforementioned example, while the pressure in the load lock chamber 11 is set to the first load pressure value LP1 higher than the pressure in the local transport chamber 21, the load transport gate GLT is opened (Step S5 and Step S16). Thus, it is possible to reduce the possibility that the gas and impurities in the dry processing chamber 31 flow into the load lock chamber 11 through the local transport chamber 21.

In the aforementioned example, the first pressure regulator 15 reduces the pressure in the load lock chamber 11 to the second load pressure value LP2 lower than the first load pressure value LP1 while the load transport gate GLT is closed (Step S3 and Step S17). This allows many more impurities to more reliably be discharged from the load lock chamber 11, even when impurities slightly flow into the load lock chamber 11. Thus, the internal space of the load lock chamber 11 can be further cleaned.

This is particularly effective when the load lock chamber 11 is provided one-to-one with the local transport chamber 21. The same applies to the local transport chamber 21 and the dry processing chamber 31.

The load lock chamber 11 is more distant from the dry processing chamber 31 than the local transport chamber 21. Thus, the gas in the dry processing chamber 31 hardly flows into the load lock chamber 11. Thereby, the first pressure regulator 15 may increase the pressure in the load lock chamber 11 from the first load pressure value LP1 to the atmospheric value LP0, without reducing the pressure to the second load pressure value LP2. In other words, Step S17 need not be executed. This allows the first pressure regulator 15 to increase the pressure in the load lock chamber 11 from the first load pressure value LP1 to the atmospheric value LP0 more promptly. In this case, the first load pressure value LP1 may be higher than the first transport pressure value TP1. This allows the first pressure regulator 15 to increase the pressure in the load lock chamber 11 to the atmospheric value LP0 more promptly.

In the aforementioned example, the dry processing module 1A includes the load lock chamber 11, the local transport chamber 21, and the dry processing chamber 31. However, the dry processing module 1A is not always limited to this. For example, the dry processing module 1A does not include the load transport gate GLT, and the load lock chamber 11 and the local transport chamber 21 may always communicate with each other. In this case, the load lock chamber 11 and the local transport chamber 21 form a single chamber (corresponding to an example upstream chamber). In this case, one of the first pressure regulator 15 and the second pressure regulator 25 (corresponding to an example upstream pressure regulator) is provided, and the other is omitted.

### [Suction Part]

In the example of FIG. 3, the first suction pipe 161 connected to the load lock chamber 11 and the second suction pipe 261 connected to the local transport chamber 21 are connected to the common suction part VP. For example, downstream ends of the first suction pipe 161 and the second suction pipe 261 are connected to an upstream end of a common pipe, and a downstream end of the common pipe is connected to the suction part VP. Hereinafter, the suction part VP will be referred to as a first suction part VP1. In the example of FIG. 3, the first suction part VP1 is not connected to the third suction pipe 361.

Upon the first suction part VP1 being operated, the first suction part VP1 suctions gas in the load lock chamber 11 through the first suction pipe 161, and suctions gas in the local transport chamber 21 through the second suction pipe 261. In other words, the first suction part VP1 is shared by the load lock chamber 11 and the local transport chamber 21. Thus, the number of suction parts VP can be reduced, and the manufacturing cost can be reduced.

In the example of FIG. 3, the third suction pipe 361 connected to the dry processing chamber 31 is connected to another suction part VP (hereinafter referred to as a second suction part VP2) that is different from the first suction part VP1. In the example of FIG. 3, the second suction part VP2 is connected neither to the first suction pipe 161 nor to the second suction pipe 261. Upon the second suction part VP2 being operated, the second suction part VP2 suctions gas in the dry processing chamber 31 through the third suction pipe 361. Consequently, neither the gas from the load lock chamber 11 nor the gas from the local transport chamber 21 flow into the third suction pipe 361 and the second suction part VP2. Thus, the third pressure regulating valve 362 can regulate the pressure in the dry processing chamber 31 without any influence of these gases. In other words, the pressure variation in the dry processing chamber 31 which is caused by the gases can be avoided. This allows the third pressure regulating valve 362 to regulate the pressure in the dry processing chamber 31 with higher accuracy. Since a pressure value in the dry processing chamber 31 influences a result of the dry process on the substrate W, the dry processing unit 30 can perform the dry process on the substrate W with higher accuracy.

### [Dry Tower]

In the example of FIG. 3, a plurality of (two herein) dry processing modules 1A are stacked in the vertical direction to form one tower TW. The tower TW in FIG. 3 does not include the wet processing module 1B. Hereinafter, the tower TW that does not include the wet processing module 1B and includes two or more dry processing modules 1A will also be referred to as a dry tower TWA.

In the example of FIG. 3, a piping space PS is provided immediately below the entirety of the load lock chamber 11, the local transport chamber 21, and the dry processing chamber 31 (i.e., a dry chamber) in the dry tower TWA. Assuming that a space in which the dry chamber is provided is referred to as a chamber space, the chamber space and the piping space PS are alternately provided in the vertical direction in the dry tower TWA. In the piping space PS, at least a part of a piping system of the dry processing modules 1A is provided.

In the example of FIG. 3, at least a part of the first suction pipe 161 and the first pressure regulating valve 162 are provided in the piping space PS. Thus, the first pressure regulating valve 162 is provided near the load lock chamber 11. Thus, the first pressure regulating valve 162 can regulate the pressure in the load lock chamber 11 with higher accuracy. In the example of FIG. 3, at least a part of the second suction pipe 261 and the second pressure regulating valve 262 are also provided in the piping space PS. This allows the second pressure regulating valve 262 to regulate the pressure in the local transport chamber 21 with higher accuracy. In the example of FIG. 3, at least a part of the third suction pipe 361 and the third pressure regulating valve 362 are also provided in the piping space PS. This allows the third pressure regulating valve 362 to regulate the pressure in the dry processing chamber 31 with higher accuracy.

In the example of FIG. 3, the suction parts VP are provided below the dry tower TWA. For example, the dry tower TWA may be provided above the floor, and the suction parts VP may be provided downstairs (under the floor). Since the suction parts VP are larger than, for example, the first pressure regulating valve 162, disposing the suction parts VP with such a large size below the dry tower TWA can reduce the height of each of the piping spaces PS. This can further reduce the height of the dry tower TWA.

In the example of FIG. 3, at least a part of the first supply pipe 171 and the first supply valve 172 are provided in the piping space PS. Thus, the first supply valve 172 is provided near the load lock chamber 11. Thus, the first supply valve 172 can switch between supplying gas to the load lock chamber 11 and stop supplying the gas with high responsiveness. In the example of FIG. 3, at least a part of the second supply pipe 271 and the second supply valve 272 are also provided in the piping space PS. Thus, the second supply valve 272 can switch between supplying gas to the local transport chamber 21 and stop supplying the gas with high responsiveness. At least a part of the third supply pipe 371 and the third supply valve 372 may be also provided in the piping space PS. Thus, the third supply valve 372 can switch between supplying gas to the dry processing chamber 31 and stop supplying the gas with high responsiveness.

In the aforementioned example, the dry tower TWA does not include the wet processing module 1B. Thus, pipes for the dry processing modules 1A and pipes for the wet processing module 1B are not mixed together in the dry tower TWA. Thus, a structure of the pipes in the dry tower TWA can be simplified.

### Embodiment 2

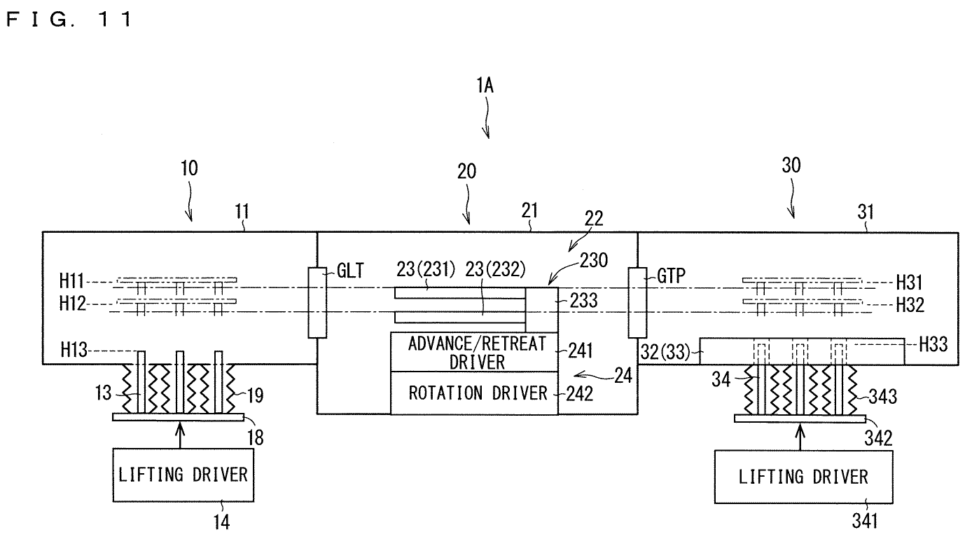

FIG. 11 is a diagram schematically illustrating an example structure of a transport system of the dry processing module 1A according to Embodiment 2. In the example of FIG. 11, the local transporter 22 includes a plurality of hands 23. FIG. 11 illustrates two hands 23. Hereinafter, one of the hands 23 will be referred to as a first hand 231, and the other hand 23 will be referred to as a second hand 232. The first hand 231 and the second hand 232 are aligned at an interval in the vertical direction. Here, the second hand 232 is disposed below the first hand 231. The interval between the first hand 231 and the second hand 232 is greater than the thickness of the substrate W. The interval may be set narrow as much as possible, for example, 25 mm or less.

The first hand 231 and the second hand 232 may have the same shape in a plan view. The first hand 231 and the second hand 232 may be provided in an overlapping manner in a plan view. The first hand 231 and the second hand 232 are fixed by a joint part 233. In other words, a relative position relationship between the first hand 231 and the second hand 232 is constant, and the interval between the first hand 231 and the second hand 232 is fixed. With also reference to FIG. 1, for example, the hands 23 (the first hand 231 and the second hand 232) include one or more elongated parts 23a.

With also reference to FIG. 1, for example, the first hand 231 includes the one or more elongated parts 23a. In the example of FIG. 1, a plurality (specifically, two) of the elongated parts 23a are disposed. The elongated parts 23a are adjacent to each other in a plan view, and base ends of the elongated parts 23a are coupled by a joint part 23b. The second hand 232 may include elongated parts 23a and a joint part 23b, similarly to the first hand 231. The joint part 233 is fixed by, for example, the joint part 23b of the first hand 231 and the joint part 23b of the second hand 232. Hereinafter, a portion including the first hand 231, the second hand 232, and the joint part 233 will be referred to as an end effector 230.

The hand movement driver 24 is controlled by the controller 90, and moves the end effector 230 along the horizontal direction. In other words, the hand movement driver 24 moves the first hand 231 and the second hand 232 in unison along the horizontal direction. For example, the hand movement driver 24 includes a driving source such as a motor, and a power transmitter that transmits a driving force of the driving source to the hands 23. The power transmitter includes, for example, at least one of an arm mechanism, a ball screw mechanism, a rotation mechanism, and a cam mechanism. As a specific example, the hand movement driver 24 includes an advance/retreat driver 241 and a rotation driver 242 in FIG. 11.

The advance/retreat driver 241 moves the end effector 230 along the horizontal direction (hereinafter referred to as an advance/retreat direction). The advance/retreat direction is, for example, a direction along an elongated direction of the elongated parts 23a. The advance/retreat driver 241 includes, for example, a plurality of arms and a motor that regulates a connection angle of the arms. One end of a connection body including the plurality of arms is connected to the end effector 230, and the other end of the connection body is connected to the rotation driver 242. The hands 23 move along the advance/retreat direction by regulating the connection angle of the arms. The advance/retreat driver 241 may include a direct-acting mechanism such as a ball screw mechanism, instead of driving the arms.

The rotation driver 242 includes a motor, and rotates the end effector 230 and the advance/retreat driver 241 in unison about a rotation axis line along the vertical direction. This rotation can adjust the orientation of the end effector 230. Specifically, the rotation driver 242 rotates the end effector 230 between a load rotation position and a processing rotation position to be described next. The load rotation position is a rotation position at which tips of the elongated parts 23a face the load lock unit 10, and the processing rotation position is a rotation position at which the tips of the elongated parts 23a face the dry processing unit 30.

In the example of FIG. 11, the hand movement driver 24 does not include a lifting driver that lifts and lowers the end effector 230.

The dry processing unit 30 includes the plurality of lift pins 34 that are example supporting components for supporting the substrate W, and the pin lifting driver 341. The pin lifting driver 341 moves the plurality of lift pins 34 at least to each of a first height position H31, a second height position H32, and a third height position H33 to be described next. The first height position H31 is a position at which the tips of the lift pins 34 are higher than the first hand 231. The substrate W supported at the first height position H31 is located above the first hand 231. The second height position H32 is a position at which the lift pins 34 can support the substrate W between the first hand 231 and the second hand 232. The substrate W supported at the second height position H32 is away from both of the first hand 231 and the second hand 232. At the second height position H32, the tips of the lift pins 34 are located between the first hand 231 and the second hand 232. The third height position H33 is a position at which the tips of the lift pins 34 are lower than the second hand 232. In the example of FIG. 11, the tips of the lift pins 34 are located below the upper surface of the stage 33 at the third height position H33. A difference (a height width) between the first height position H31 and the third height position H33 is larger than a height width between the upper surface of the first hand 231 and the lower surface of the second hand 232. This difference is, for example, 35 mm or less.

In the example of FIG. 3, the stage 33 is disposed in the dry processing unit 30. The first height position H31 and the second height position H32 are positions at which the tips of the lift pins 34 are higher than the upper surface of the stage 33, and the third height position H33 is a position at which the tips of the lift pins 34 are lower than the upper surface of the stage 33.

In the example of FIG. 11, the load lock unit 10 includes the plurality of support pins 13 that are example supporting components for supporting the substrate W, and the pin lifting driver 14. The pin lifting driver 14 may move the plurality of support pins 13 at least to each of a first height position H11, a second height position H12, and a third height position H13 to be described next. A relative position relationship between the first height position H11 and the end effector 230 is identical to that between the first height position H31 and the end effector 230. In other words, the first height position H11 is a position at which the tips of the support pins 13 are higher than the first hand 231. The same applies to the second height position H12 and the third height position H13. In other words, the second height position H12 is a position at which the tips of the support pins 13 are located between the first hand 231 and the second hand 232, and the third height position H13 is a position at which the tips of the support pins 13 are located below the second hand 232.

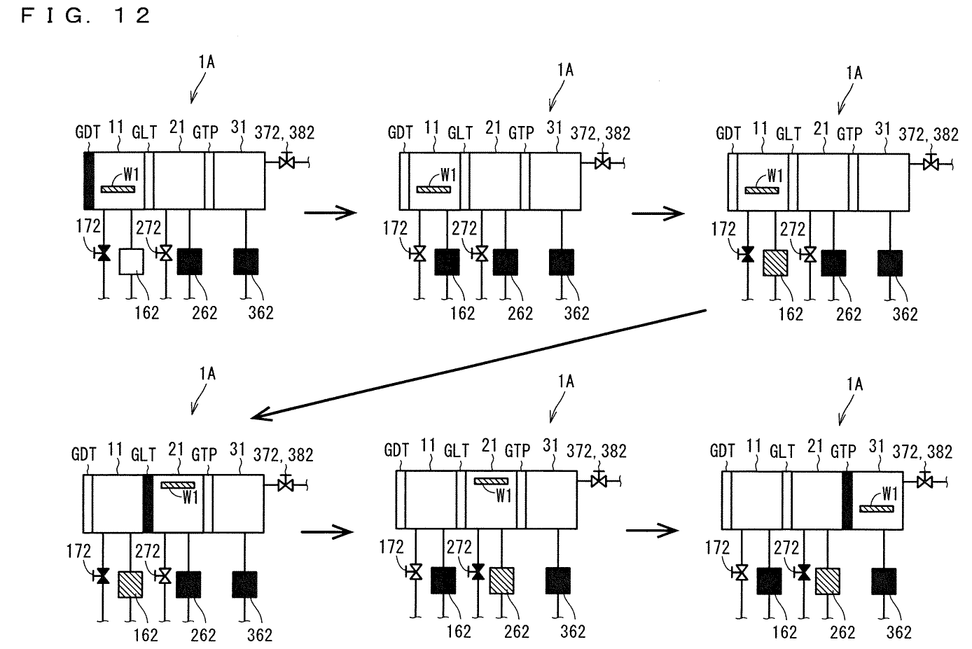

A pressure is regulated in this dry processing module 1A, similarly to Embodiment 1. FIGS. 12 to 15 are diagrams schematically illustrating example state changes during operations of the dry processing module 1A according to Embodiment 2. Hereinafter, example operations when three substrates W are sequentially transported to the dry processing module 1A will be described. Hereinafter, the substrate W to be initially transported to the dry processing module 1A will be referred to as a first substrate W1, the substrate W to be transported next to the first substrate W1 to the dry processing module 1A will be referred to as a second substrate W2, and the substrate W to be transported next to the second substrate W2 to the dry processing module 1A will be referred to as a third substrate W3.

First, the first pressure regulator 15 regulates a pressure in the load lock chamber 11 in the atmospheric range. Then, the main transporter 80 loads the first substrate W1 into the load lock chamber 11 (see the upper left of FIG. 12).

Next, the first pressure regulator 15 regulates the pressure in the load lock chamber 11 in a vacuum range. For example, the first pressure regulator 15 temporarily reduces the pressure in the load lock chamber 11 to the second load pressure value LP2, and then regulates the pressure to the first load pressure value LP1. As a specific example, the controller 90 first closes the first supply valve 172, and maintains the first pressure regulating valve 162 at the predetermined first degree of opening (e.g., a fully open position) (see the upper middle of FIG. 12). This reduces the pressure in the load lock chamber 11 up to the second load pressure value LP2. Next, the controller 90 opens the first supply valve 172 and controls the first pressure regulating valve 162 (see the upper right of FIG. 12). This regulates the pressure in the load lock chamber 11 to the first load pressure value LP1.

Next, the controller 90 opens the load transport gate GLT. Then, the controller 90 controls the pin lifting driver 14 and the local transporter 22 such that the first substrate W1 is transported from the load lock unit 10 to the local transport unit 20 (see the lower left of FIG. 12). For example, the local transporter 22 transports the first substrate W1 using the first hand 231. For example, the controller 90 controls the local transporter 22 such that the end effector 230 is moved immediately below the first substrate W1, while controlling the pin lifting driver 14 such that the support pins 13 are stopped at the first height position H11. Then, the controller 90 controls the pin lifting driver 14 such that the support pins 13 are lowered to the second height position H12 or the third height position H13. This passes the first substrate W1 to the first hand 231. Then, the controller 90 controls the local transporter 22 such that the end effector 230 is moved within the local transport chamber 21. This allows the first substrate W1 to be supported by the first hand 231 in the local transport chamber 21. Next, the controller 90 closes the load transport gate GLT.

Since the pressure in the load lock chamber 11 is higher than the pressure in the local transport chamber 21 during this transport, it is possible to reduce the possibility that the gas in the local transport chamber 21 flows into the load lock chamber 11, similarly to Embodiment 1.

Next, the controller 90 controls the second pressure regulator 25 such that the pressure in the local transport chamber 21 is regulated to the first transport pressure value TP1. For example, the controller 90 opens the second supply valve 272, and controls the second pressure regulating valve 262 (see the lower middle of FIG. 12).

Next, the controller 90 opens the transport processing gate GTP. Then, the controller 90 controls the local transporter 22 and the pin lifting driver 341 such that the first substrate W1 is transported to the dry processing unit 30 (see the lower right of FIG. 12). For example, the controller 90 first controls the local transporter 22 such that the end effector 230 is moved immediately above the lift pins 34. Then, the controller 90 controls the pin lifting driver 341 such that the lift pins 34 are lifted, for example, from the third height position H33 to the first height position H31. This passes the first substrate W1 to the lift pins 34. Next, the controller 90 controls the local transporter 22 such that the end effector 230 is moved within the local transport chamber 21, and controls the pin lifting driver 341 such that the lift pins 34 are lowered to the third height position H33. This passes the first substrate W1 to the stage 33. Then, the controller 90 closes the transport processing gate GTP.

During this transport, the pressure in the local transport chamber 21 is higher than the pressure in the dry processing chamber 31. Thus, it is possible to reduce the possibility that the gas in the dry processing chamber 31 flows into the local transport chamber 21, similarly to Embodiment 1.

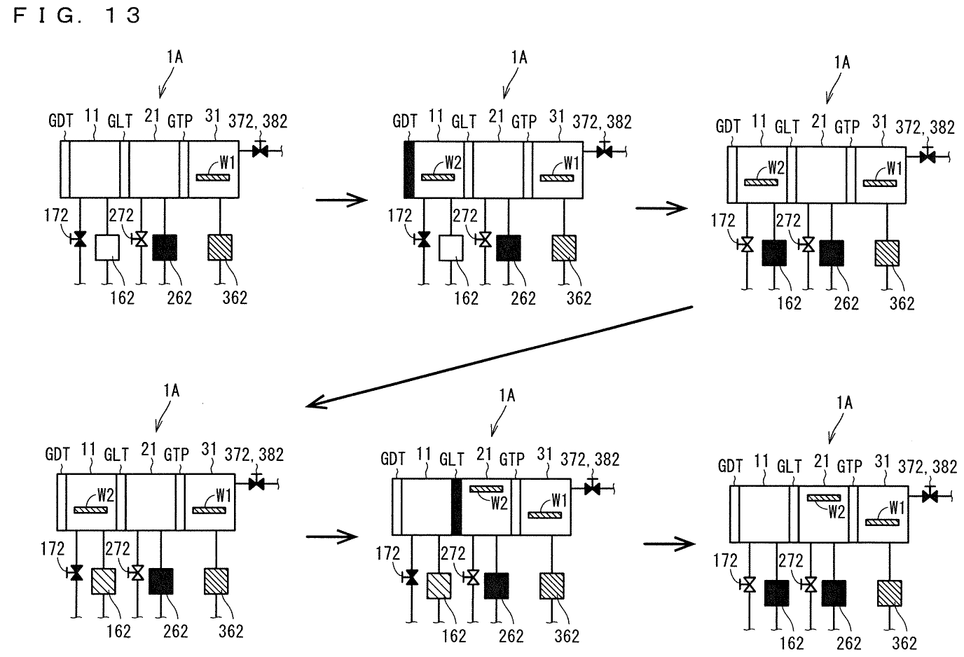

Next, the controller 90 controls the third pressure regulator 35 and the processing gas supply part 38 such that the dry process is performed on the first substrate W1 (see the upper left of FIG. 13).

On the other hand, the controller 90 may control the first pressure regulator 15 such that the pressure in the load lock chamber 11 is temporarily reduced to the second load pressure value LP2, after the load transport gate GLT is closed. As a specific example, the controller 90 may first close the first supply valve 172, and maintain the first pressure regulating valve 162 at a predetermined degree of opening (see the lower middle of FIG. 12). Thus, the internal space of the load lock chamber 11 can be further cleaned.

Next, the controller 90 controls the first pressure regulator 15 such that the pressure in the load lock chamber 11 is regulated in the atmospheric range. For example, the controller 90 opens the first supply valve 172, and closes the first pressure regulating valve 162 (see the upper left of FIG. 13).

Next, the controller 90 opens the dry transport gate GDT, and controls the main transporter 80 such that the second substrate W2 is loaded into the load lock chamber 11 (see the upper middle of FIG. 13). Then, the controller 90 closes the dry transport gate GDT.

Next, the controller 90 may control the first pressure regulator 15 such that the pressure in the load lock chamber 11 is temporarily reduced to the second load pressure value LP2. For example, the controller 90 closes the first supply valve 172 and opens the first pressure regulating valve 162 at the predetermined first degree of opening (see the upper right of FIG. 13).

Next, the controller 90 controls the first pressure regulator 15 such that the pressure in the load lock chamber 11 is regulated to the first load pressure value LP1. For example, the controller 90 opens the first supply valve 172, and controls the first pressure regulating valve 162 (see the lower left of FIG. 13).

Next, the controller 90 opens the load transport gate GLT. Then, the controller 90 controls the pin lifting driver 14 and the local transporter 22 such that the second substrate W2 is transported from the load lock unit 10 to the local transport unit 20. For example, the local transporter 22 transports the second substrate W2 using the first hand 231. This allows the second substrate W2 to be supported by the first hand 231 in the local transport chamber 21 (see the lower middle of FIG. 13). Then, the controller 90 closes the load transport gate GLT. The second substrate W2 waits in the local transport chamber 21 until the end of the dry process on the first substrate W1 (see the lower right of FIG. 13).

On the other hand, the controller 90 may control the first pressure regulator 15 such that the pressure in the load lock chamber 11 is temporarily reduced to the second load pressure value LP2, after the load transport gate GLT is closed. For example, the controller 90 may close the first supply valve 172, and maintain the first pressure regulating valve 162 at a predetermined degree of opening (see the lower right of FIG. 13). Thus, the internal space of the load lock chamber 11 can be further cleaned.

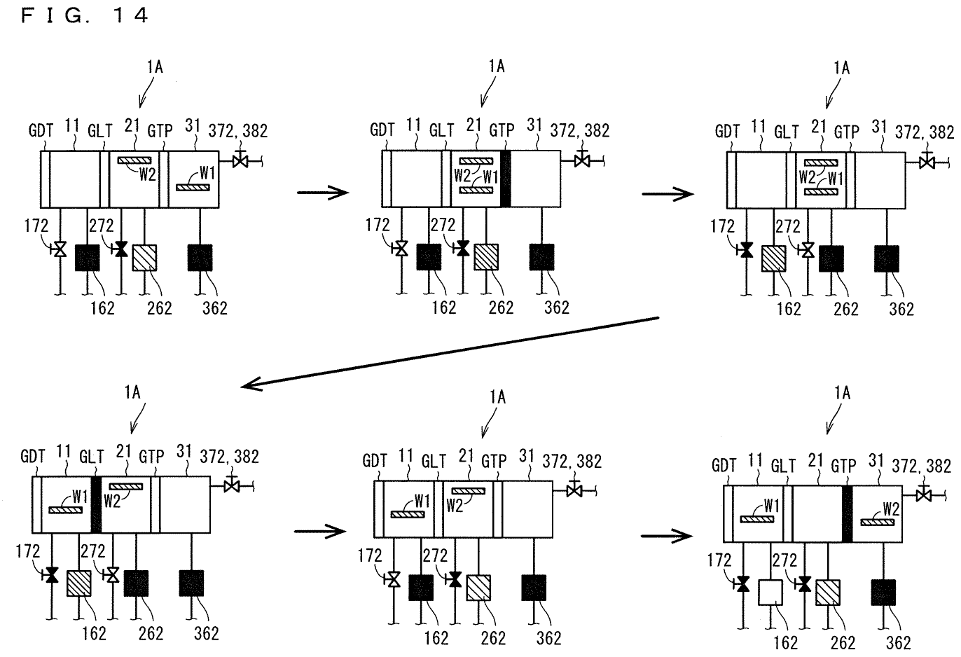

When the dry process on the first substrate W1 ends, the first substrate W1 is unloaded from the dry processing chamber 31. Before the first substrate W1 is unloaded from this dry processing chamber 31, the controller 90 controls the second pressure regulator 25 such that the pressure in the local transport chamber 21 is increased to the first transport pressure value TP1. For example, the controller 90 opens the second supply valve 272, and controls the second pressure regulating valve 262 (see the upper left of FIG. 14).

Next, the controller 90 opens the transport processing gate GTP. Then, the controller 90 controls the local transporter 22 and the pin lifting driver 341 such that the first substrate W1 is transported from the dry processing unit 30 to the local transport unit 20 (see the upper middle of FIG. 14). Since the first hand 231 supports the second substrate W2, the first substrate W1 is transported using the second hand 232. For example, the controller 90 controls the pin lifting driver 341 such that the lift pins 34 are lifted from the third height position H33 to the second height position H32. This passes the first substrate W1 from the stage 33 to the lift pins 34. Since the lift pins 34 are located at the second height position H32, the first substrate W1 is located between the first hand 231 and the second hand 232. Next, the controller 90 controls the local transporter 22 such that the end effector 230 is moved to a position at which the second hand 232 is immediately below the first substrate W1. Then, the controller 90 controls the pin lifting driver 341 such that the lift pins 34 are lowered to the third height position H33. This passes the first substrate W1 to the second hand 232. Next, the controller 90 controls the local transporter 22 such that the end effector 230 is moved inside the local transport chamber 21. This allows the first substrate W1 and the second substrate W2 to be supported by the second hand 232 and the first hand 231, respectively, in the local transport chamber 21. Then, the controller 90 closes the transport processing gate GTP.

Since the pressure in the local transport chamber 21 is higher than the pressure in the dry processing chamber 31 during this transport, it is possible to reduce the possibility that the gas in the dry processing chamber 31 flows into the local transport chamber 21, similarly to Embodiment 1.

Next, the first substrate W1 is transported from the local transport unit 20 to the load lock unit 10. First, the controller 90 may control the second pressure regulator 25 such that the pressure in the local transport chamber 21 is reduced to the second transport pressure value TP2. For example, the controller 90 closes the second supply valve 272, and maintains the second pressure regulating valve 262 at the predetermined second degree of opening (see the upper right of FIG. 14). Thus, the internal space of the local transport chamber 21 can be further cleaned. Furthermore, the controller 90 controls the first pressure regulator 15 such that the pressure in the load lock chamber 11 is increased to the first load pressure value LP1. For example, the controller 90 opens the first supply valve 172, and controls the first pressure regulating valve 162 (see the upper right of FIG. 14).

Next, the controller 90 opens the load transport gate GLT. Then, the controller 90 controls the pin lifting driver 14 and the local transporter 22 such that the first substrate W1 is loaded into the load lock chamber 11 (see the lower left of FIG. 14). For example, the controller 90 controls the local transporter 22 such that the end effector 230 is moved immediately above the support pins 13, and then controls the pin lifting driver 14 such that the support pins 13 are lifted from the third height position H13 to the second height position H12. This passes the first substrate W1 to the support pins 13. Next, the controller 90 controls the local transporter 22 such that the end effector 230 is moved inside the local transport chamber 21. Then, the controller 90 closes the load transport gate GLT.

Next, the second substrate W2 is transported to the dry processing unit 30. First, the controller 90 controls the second pressure regulator 25 such that the pressure in the local transport chamber 21 is regulated to the first transport pressure value TP1. For example, the controller 90 opens the second supply valve 272, and controls the second pressure regulating valve 262 (see the lower middle of FIG. 14).

Next, the controller 90 opens the transport processing gate GTP. Then, the controller 90 controls the local transporter 22 and the pin lifting driver 341 such that the second substrate W2 is transported to the dry processing unit 30 (see the lower right of FIG. 14). Next, the controller 90 closes the transport processing gate GTP.

Since the pressure in the local transport chamber 21 is higher than the pressure in the dry processing chamber 31 during this transport, it is possible to reduce the possibility that the gas in the dry processing chamber 31 flows into the local transport chamber 21.

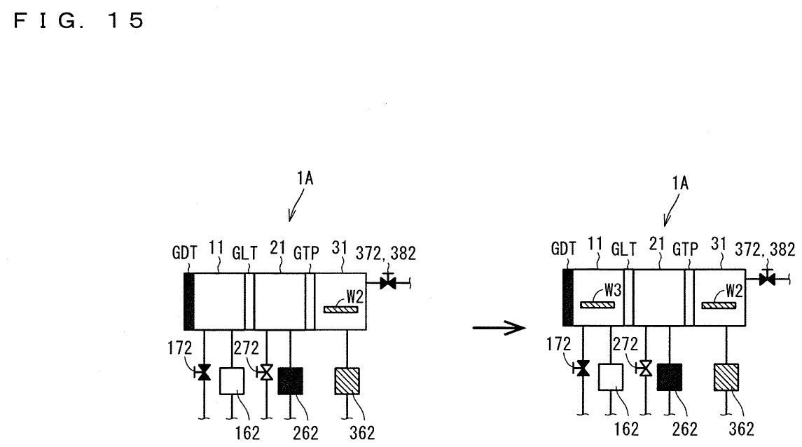

Next, the controller 90 controls the third pressure regulator 35 and the processing gas supply part 38 such that the dry process is performed on the second substrate W2 (see the left of FIG. 15).

On the other hand, the controller 90 controls the first pressure regulator 15 such that the pressure in the load lock chamber 11 is regulated in the atmospheric range, after the load transport gate GLT is closed. Here, the controller 90 controls the first pressure regulator 15 such that the pressure is temporarily reduced to the second load pressure value LP2. For example, the controller 90 closes the first supply valve 172, and maintains the first pressure regulating valve 162 at the predetermined first degree of opening (see the lower middle of FIG. 14).

Next, the controller 90 controls the first pressure regulator 15 such that the pressure in the load lock chamber 11 is regulated to the atmospheric value LP0. For example, the controller 90 opens the first supply valve 172, and closes the first pressure regulating valve 162 (see the lower right of FIG. 14).

Next, the controller 90 opens the dry transport gate GDT. Then, the controller 90 controls the main transporter 80 such that the first substrate W1 is unloaded from the load lock chamber 11 (see the left of FIG. 15).

Then, the controller 90 controls the main transporter 80 such that the third substrate W3 is loaded into the load lock chamber 11 (see the right of FIG. 15). From then on, the same operations are sequentially performed on the substrates W.

As described above, it is possible to reduce the possibility that impurities in the dry processing chamber 31 flow into each of the local transport chamber 21 and the load lock chamber 11 in Embodiment 2, similarly to Embodiment 1. Thus, the possibility of contaminating the substrates W can be reduced.

In Embodiment 2, during a period in which the dry processing unit 30 performs the dry process on a preceding substrate W (e.g., the first substrate W1), a succeeding substrate W waits within the dry processing module 1A in a vacuum condition. In the aforementioned example, the succeeding substrate W waits within the local transport chamber 21. In other words, pressure regulation for transporting the succeeding second substrate W2 (pressure regulation in the load lock chamber 11) is completed until the end of the dry process on the preceding first substrate W1. Thus, the succeeding second substrate W2 can be loaded into the dry processing chamber 31 more promptly after the end of the dry process on the preceding first substrate W1. This can increase the throughput of the substrate processing apparatus 100.

When the dry process is, for example, an etching process of etching an etching target film of the substrate W, there is a danger that a by-product generated from a reaction between a processing gas and the substrate W may adhere to the substrate W as impurities. Then, there is also a danger that the adhering object may drop from the substrate W that has been subjected to the dry process, during transport of this substrate W.

Thus, the substrate W that has been subjected to the dry process may be transported by the lower second hand 232, and a substrate W to be subjected to the dry process may be transported by the upper first hand 231 as described above. Since the first hand 231 is located above the second hand 232, the substrate W to be subjected to the dry process is transported along the horizontal direction at a position higher than the substrate W that has been subjected to the dry process. Thus, even when the impurities adhering to this substrate W that has been subjected to the dry process drop during transport of the substrate W in the horizontal direction, a transport route of the succeeding substrate W to be subjected to the dry process is not contaminated. Consequently, the possibility of contaminating the substrate W to be subjected to the dry process can be reduced.

Furthermore, in the example of FIG. 11, the load lock unit 10 includes the pin lifting driver 14, and the dry processing unit 30 includes the pin lifting driver 341. In other words, the load lock unit 10 and the dry processing unit 30 have a function of lifting and lowering the substrate W. Thus, the local transport unit 20 need not have the function of lifting and lowering the substrate W. Thereby, no lifting driver is provided for the hand movement driver 24 in the local transport unit 20 in the example of FIG. 11. Thus, the size of the local transport unit 20 in the vertical direction can be reduced. In other words, since the local transporter 22 includes the hand movement driver 24 that moves the hands 23, its size in the vertical direction is supposed to become large. Here, omitting a lifting driver can effectively reduce the size of the local transport unit 20 in the vertical direction. On the other hand, the load lock unit 10 should support the substrate W, and need not have a function of moving the substrate W in the horizontal direction. Even when the load lock unit 10 includes a lifting driver for the substrate W, its size in the vertical direction is not as large as that in the local transport unit 20. The same applies to the dry processing unit 30.

When the local transport unit 20 does not include a lifting driver, the end effector 230 is neither lifted nor lowered. Thus, the height width of the load transport gate GLT and the height width of the transport processing gate GTP can be reduced. This can increase the flow velocity of the gas flowing from the load lock chamber 11 into the local transport chamber 21 through the load transport gate GLT during transport of the substrate W. Thus, the possibility of an inflow of gas from the local transport chamber 21 into the load lock chamber 11 can further be reduced. The possibility of an inflow of gas from the dry processing chamber 31 into the local transport chamber 21 can further be reduced.

### [Bellows]

In the example of FIG. 11, the pin lifting driver 14 is disposed in an external space of the load lock chamber 11. In the example of FIG. 11, the lower ends of the support pins 13 are connected to an upper surface of a support plate 18. The support plate 18 is, for example, plate-shaped, and is disposed in an attitude such that its thickness direction is along the vertical direction. In the example of FIG. 11, an opening is formed at the bottom of the load lock chamber 11, and the support pins 13 are disposed to penetrate this opening. In the example of FIG. 11, bellows 19 are provided between the bottom of the load lock chamber 11 and the support plate 18. The bellows 19 are of a tubular and accordion-like shape. In the example of FIG. 11, the bellows 19 that surround the lower portions of the support pins 13 are provided. The bellows 19 are deformable in the vertical direction. In other words, the size of the bellows 19 in the vertical direction is variable. A top circumferential edge of the bellows 19 is connected to an outer edge of the opening of the load lock chamber 11, and a bottom circumferential edge of the bellows 19 is connected to an outer edge of the support plate 18.

The pin lifting driver 14 is disposed below the support plate 18. The pin lifting driver 14 is connected to the support plate 18, and lifts and lowers the support plate 18. Accordingly, the support pins 13 connected to the support plate 18 are lifted and lowered. As illustrated in FIG. 11, the bellows 19 are provided one-to-one with the support pins 13. This can reduce the volumetric capacity of a vacuum portion in the load lock chamber 11 more than that in a structure including a single bellow surrounding the support pins 13. Thus, the first pressure regulator 15 can regulate the pressure in the load lock chamber 11 with higher accuracy.

Since the pin lifting driver 14 is disposed outside the load lock chamber 11, the pin lifting driver 14 can be disposed in an atmospheric space (e.g., the piping space PS). Thus, the reliability of the pin lifting driver 14 can be enhanced.

In the example of FIG. 11, the pin lifting driver 341 is disposed in an external space of the dry processing chamber 31. In the example of FIG. 11, the lower ends of the lift pins 34 are connected to an upper surface of a support plate 342. Bellows 343 are provided between the bottom of the dry processing chamber 31 and the support plate 342. In the example of FIG. 11, the bellows 343 that surround the lower portions of the lift pins 34 are provided. These are identical to the support plate 18 and the bellows 19.

While the substrate processing apparatus 100 and a method of processing a substrate are described in detail above, the description is in all aspects illustrative and does not restrict this disclosure. The aforementioned various modifications are applicable in combination unless any contradiction occurs. Therefore, numerous modifications and variations that have not yet been exemplified are devised without departing from the scope of the present disclosure.

For example, the first pressure regulating valve 162 is disposed in the first suction pipe 161 in the aforementioned example. However, the first pressure regulating valve 162 may be disposed in the first supply pipe 171. Similarly, the second pressure regulating valve 262 may be disposed in the second supply pipe 271. The third pressure regulating valve 362 may be disposed in the third supply pipe 371.

The present disclosure includes the following aspects.

A first aspect is a substrate processing apparatus that includes: an upstream chamber; an upstream pressure regulator that supplies gas to the upstream chamber and suctions the gas from the upstream chamber to regulate a pressure in the upstream chamber; a dry processing chamber that is connected to the upstream chamber through a first gate and that performs a dry process on a substrate while the first gate is closed; a transporter that transports the substrate between the upstream chamber and the dry processing chamber through the first gate that is opened; and a controller that controls the upstream pressure regulator such that a pressure in the upstream chamber is set to a first pressure value higher than a pressure in the dry processing chamber, opens the first gate and controls the transporter such that the substrate is transported while the pressure in the upstream chamber is set to the first pressure value, and controls the upstream pressure regulator such that the pressure in the upstream chamber is reduced to a second pressure value lower than the first pressure value while the first gate is closed.

A second aspect is the substrate processing apparatus according to the first aspect, wherein the upstream chamber is provided one-to-one with the dry processing chamber.

A third aspect is the substrate processing apparatus according to the first or second aspect, wherein the upstream pressure regulator includes: a supply pipe connected to the upstream chamber; and a supply valve disposed in the supply pipe, and the controller closes the supply valve to reduce the pressure in the upstream chamber to the second pressure value.

A fourth aspect is the substrate processing apparatus according to any one of the first to third aspects, wherein the upstream pressure regulator includes: a suction pipe connected to the upstream chamber; and a pressure regulating valve disposed in the suction pipe, and the controller maintains a degree of opening of the pressure regulating valve at a predetermined degree of opening to reduce the pressure in the upstream chamber to the second pressure value.

A fifth aspect is the substrate processing apparatus according to any one of the first to fourth aspects, the substrate processing apparatus including: a load lock chamber connected, through a second gate, to a local transport chamber that is the upstream chamber; and a load pressure regulator that supplies the gas to the load lock chamber and suctions the gas from the load lock chamber to regulate a pressure in the load lock chamber, wherein the controller controls the load pressure regulator such that the pressure in the load lock chamber is set to a first load pressure value higher than a pressure in the local transport chamber, and opens the second gate and controls the transporter such that the substrate is transported between the load lock chamber and the local transport chamber while the pressure in the load lock chamber is set to the first load pressure value, and the controller controls the load pressure regulator such that the pressure in the load lock chamber is reduced to a second load pressure value lower than the first load pressure value while the second gate is closed.

A sixth aspect is the substrate processing apparatus according to the fifth aspect, the substrate processing apparatus including a dry pressure regulator that regulates a pressure in the dry processing chamber, wherein the load pressure regulator includes a first suction pipe connected to the load lock chamber, the upstream pressure regulator includes a second suction pipe connected to the upstream chamber, the load pressure regulator and the upstream pressure regulator include a first suction part connected to the first suction pipe and the second suction pipe, and the dry pressure regulator includes: a third suction pipe connected to the dry processing chamber; and a second suction part connected to the third suction pipe.

A seventh aspect is a method of processing a substrate, the method including: a first step of opening a first gate between an upstream chamber and a dry processing chamber and transporting a substrate between the upstream chamber and the dry processing chamber using a transporter, while a pressure in the upstream chamber is set to a first pressure value higher than a pressure in the dry processing chamber; and a second step of reducing the pressure in the upstream chamber to a second pressure value lower than the first pressure value while the first gate is closed.

According to the first and seventh aspects, since the pressure in the upstream chamber is higher than the pressure in the dry processing chamber during the transport, it is possible to reduce the possibility that the gas and impurities in the dry processing chamber flow into the upstream chamber. Furthermore, the pressure in the upstream chamber is reduced to the second pressure value while the first gate is closed. Even when impurities flow into the upstream chamber, the impurities can more reliably be discharged from the upstream chamber. Thus, the possibility of contaminating a substrate in the upstream chamber can be reduced.

According to the second aspect, a shielding time during which the upstream chamber is shielded from the internal space of the dry processing chamber is relatively long. Thus, it is possible to sufficiently reduce the pressure in the upstream chamber. Thus, the impurities can be sufficiently discharged from the upstream chamber.

According to the third aspect, the usage of gas can be reduced.

According to the fourth aspect, the power consumption can be reduced.

According to the fifth aspect, it is possible to reduce the possibility that the gas in the local transport chamber flows into the load lock chamber. In other words, it is possible to reduce the possibility that the gas in the dry processing chamber flows into a load lock chamber through the local transport chamber.

According to the sixth aspect, since the gas suctioned from each of the load lock chamber and the local transport chamber does not flow through the third suction pipe, the pressure variation in the dry processing chamber which is caused by the gases can be avoided.

What is claimed is:

1. A substrate processing apparatus, comprising:
an upstream chamber;
an upstream pressure regulator that supplies gas to the upstream chamber and suctions the gas from the upstream chamber to regulate a pressure in the upstream chamber;
a dry processing chamber that is connected to the upstream chamber through a first gate and that performs a dry process on a substrate while the first gate is closed;
a transporter that transports the substrate between the upstream chamber and the dry processing chamber through the first gate that is opened; and
a controller that controls the upstream pressure regulator such that a pressure in the upstream chamber is set to a first pressure value higher than a pressure in the dry processing chamber, opens the first gate and controls the transporter such that the substrate is transported while the pressure in the upstream chamber is set to the first pressure value, and controls the upstream pressure regulator such that the pressure in the upstream chamber is reduced to a second pressure value lower than the first pressure value while the first gate is closed.

2. The substrate processing apparatus according to claim 1,
wherein the upstream chamber is provided one-to-one with the dry processing chamber.

3. The substrate processing apparatus according to claim 1,
wherein the upstream pressure regulator includes:
a supply pipe connected to the upstream chamber; and
a supply valve disposed in the supply pipe, and
the controller closes the supply valve to reduce the pressure in the upstream chamber to the second pressure value.

4. The substrate processing apparatus according to claim 1,
wherein the upstream pressure regulator includes:
a suction pipe connected to the upstream chamber; and
a pressure regulating valve disposed in the suction pipe, and
the controller maintains a degree of opening of the pressure regulating valve at a predetermined degree of opening to reduce the pressure in the upstream chamber to the second pressure value.

5. The substrate processing apparatus according to claim 1, comprising:
a load lock chamber connected, through a second gate, to a local transport chamber that is the upstream chamber; and
a load pressure regulator that supplies the gas to the load lock chamber and suctions the gas from the load lock chamber to regulate a pressure in the load lock chamber,
wherein the controller controls the load pressure regulator such that the pressure in the load lock chamber is set to a first load pressure value higher than a pressure in the local transport chamber, and opens the second gate and controls the transporter such that the substrate is transported between the load lock chamber and the local transport chamber while the pressure in the load lock chamber is set to the first load pressure value, and
the controller controls the load pressure regulator such that the pressure in the load lock chamber is reduced to a second load pressure value lower than the first load pressure value while the second gate is closed.

6. The substrate processing apparatus according to claim 5, comprising
a dry pressure regulator that regulates a pressure in the dry processing chamber,
wherein the load pressure regulator includes a first suction pipe connected to the load lock chamber,
the upstream pressure regulator includes a second suction pipe connected to the upstream chamber,
the load pressure regulator and the upstream pressure regulator include a first suction part connected to the first suction pipe and the second suction pipe, and
the dry pressure regulator includes:
a third suction pipe connected to the dry processing chamber; and
a second suction part connected to the third suction pipe.

7. A method of processing a substrate, the method comprising:
opening a first gate between an upstream chamber and a dry processing chamber and transporting a substrate between the upstream chamber and the dry processing chamber using a transporter, while a pressure in the upstream chamber is set to a first pressure value higher than a pressure in the dry processing chamber; and
reducing the pressure in the upstream chamber to a second pressure value lower than the first pressure value while the first gate is closed.
